(19) United States
(12) Patent Application Publication
(10) Pub. No.: US 2015/0310793 A1
(43) Pub. Date: Oct. 29, 2015

(54) Input/output Device and Method for Driving Input/output Device

(71) Applicant: Semiconductor Energy Laboratory Co., Ltd., Kanagawa-ken (JP)

(72) Inventors: Susumu Kawashima, Atsugi (JP); Hiroyuki MIYAKE, Atsugi (JP); Koji KUSUNOKI, Kawasaki (JP); Seiko INOUE, Atsugi (JP)

(73) Assignee: Semiconductor Energy Laboratory Co., Ltd., Kanagawa-ken (JP)

(21) Appl. No.: 14/691,001

(22) Filed: Apr. 20, 2015

(30) Foreign Application Priority Data
Apr. 23, 2014 (JP) 2014-088971

(51) Int. Cl. G09G 3/20; G06F 3/041; G06F 3/044; H01L 27/12

(52) U.S. Cl. CPC G09G 3/2003; H01L 27/124; G06F 3/0412; G06F 3/044; G09G 2300/0426

(57) ABSTRACT

A novel input/output device which is highly convenient or reliable is provided. A method for driving an input/output device is provided. The present inventors have conceived a structure which includes an input/output circuit supplied with a selection signal, a control signal, a display signal including display data, and a sensing signal and capable of supplying a potential based on the sensing signal, a conversion circuit capable of supplying sensing data based on the sensing signal, a sensing element capable of supplying the sensing signal, and a display element supplied with a current.

### TECHNICAL FIELD

One embodiment of the present invention relates to an input/output device, a method for driving the input/output device, or a semiconductor device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method for driving any of them, and a method for manufacturing any of them.

### BACKGROUND ART

In the case where drain current of a driving transistor is supplied to a light-emitting element, when the threshold voltages of driving transistors vary among pixels, the luminances of light-emitting elements vary correspondingly.

A structure of a light-emitting device is known in which variation in luminance among pixels due to variation in threshold voltage among transistors is suppressed by supplying a gate electrode with a potential that is obtained by adding the threshold voltage of a driving transistor to the voltage of an image signal (Patent Document 1).

### PATENT DOCUMENT

### [Patent Document 1] Japanese Published Patent Application No. 2013-137498

### DISCLOSURE OF INVENTION

An object of one embodiment of the present invention is to provide a novel input/output device that is highly convenient or reliable. Another object of one embodiment of the present invention is to provide a novel method for driving an input/output device that is highly convenient or reliable. Another object of one embodiment of the present invention is to provide a novel input/output device, a novel method for driving an input/output device, or a novel semiconductor device.

Note that the descriptions of these objects do not disturb the existence of other objects. Note that in one embodiment of the present invention, there is no need to achieve all the objects. Other objects are apparent from and can be derived from the description of the specification, the drawings, the claims, and the like.

One embodiment of the present invention is an input/output device which includes an input/output circuit supplied with a selection signal, a control signal, a display signal including display data, and a sensing signal and capable of supplying a potential based on the sensing signal, a conversion circuit supplied with a high power supply potential and capable of supplying a potential based on the high power supply potential and supplying sensing data based on the sensing signal, a sensing element capable of supplying the sensing signal, and a display element supplied with a predetermined current.

The input/output circuit includes a first transistor. A gate of the first transistor is electrically connected to a first control line capable of supplying the selection signal. A first electrode of the first transistor is electrically connected to a signal line capable of supplying the display signal.

The input/output circuit includes a second transistor. A gate of the second transistor is electrically connected to a second control line capable of supplying the control signal. A first electrode of the second transistor is electrically connected to a first wiring.

The input/output circuit includes a driving transistor. A gate of the driving transistor is electrically connected to a second electrode of the first transistor. A first electrode of the driving transistor is electrically connected to a second wiring. A second electrode of the driving transistor is electrically connected to a second electrode of the second transistor.

The conversion circuit includes a transistor. A gate and a first electrode of the transistor are electrically connected to respective wirings each capable of supplying a high power supply potential. A second electrode of the transistor is electrically connected to the second wiring. The conversion circuit also includes a terminal electrically connected to the second wiring and capable of supplying the sensing data.

A first electrode of the sensing element is electrically connected to the second electrode of the first transistor. A second electrode of the sensing element is electrically connected to the second electrode of the second transistor.

A first electrode of the display element is electrically connected to the second electrode of the driving transistor. A second electrode of the display element is electrically connected to a third wiring.

One embodiment of the present invention is an input/output device which includes an input/output circuit supplied with a selection signal, first to third control signals, a display signal including display data, and a sensing signal and capable of supplying a potential based on the sensing signal, a conversion circuit supplied with a high power supply potential and capable of supplying a potential based on the high power supply potential and supplying sensing data based on the sensing signal, a sensing element capable of supplying the sensing signal, and a display element supplied with a predetermined current.

The input/output circuit includes a first transistor. A gate of the first transistor is electrically connected to a first control line capable of supplying the selection signal. A first electrode of the first transistor is electrically connected to a signal line capable of supplying the display signal.

The input/output circuit includes a second transistor. A gate of the second transistor is electrically connected to a second control line capable of supplying the first control signal. A first electrode of the second transistor is electrically connected to a first wiring.

The input/output circuit includes a third transistor. A gate of the third transistor is electrically connected to a third control line capable of supplying the second control signal. A first electrode of the third transistor is electrically connected to a second electrode of the second transistor.

The input/output circuit includes a fourth transistor. A gate of the fourth transistor is electrically connected to a fourth control line capable of supplying the third control signal. A first electrode of the fourth transistor is electrically connected to a second electrode of the first transistor.

The input/output circuit includes a fifth transistor. A gate of the fifth transistor is electrically connected to the first control line capable of supplying the selection signal. A first electrode of the fifth transistor is electrically connected to a second electrode of the fourth transistor. A second electrode of the fifth transistor is electrically connected to a fourth wiring.

The input/output circuit includes a driving transistor. A gate of the driving transistor is electrically connected to the second electrode of the fourth transistor. A first electrode of the driving transistor is electrically connected to a second wiring. A second electrode of the driving transistor is electrically connected to the second electrode of the second transistor.

The conversion circuit includes a transistor. A gate and a first electrode of the transistor are electrically connected to respective wirings each capable of supplying a high power supply potential. A second electrode of the transistor is electrically connected to the second wiring. The conversion circuit also includes a terminal electrically connected to the second wiring and capable of supplying the sensing data.

A first electrode of the sensing element is electrically connected to the second electrode of the first transistor. A second electrode of the sensing element is electrically connected to the second electrode of the second transistor.

A first electrode of the display element is electrically connected to a second electrode of the third transistor. A second electrode of the display element is electrically connected to a third wiring.

The input/output device in the above embodiment of the present invention includes the input/output circuit supplied with the selection signal, the control signal, the display signal including display data, and the sensing signal and capable of supplying the potential based on the sensing signal, the conversion circuit capable of supplying the sensing data based on the sensing signal, the sensing element capable of supplying the sensing signal, and the display element supplied with the predetermined current.

Accordingly, the sensing data can be supplied using a potential which changes in accordance with the sensing signal supplied by the sensing element, and the display data can be displayed by the display element using the predetermined current based on the display signal. Thus, a novel input/output device which is highly convenient or reliable can be provided.

In the above input/output device in one embodiment of the present invention, the sensing signal supplied by the sensing element may include a current which changes with a change in capacitance.

In the above input/output device in one embodiment of the present invention, the display element includes the first electrode, the second electrode overlapping with the first electrode, and a layer containing a light-emitting organic compound between the first electrode and the second electrode.

Accordingly, sensing data on a change in distance from the sensing element to an object having a higher dielectric constant than the air can be supplied, and display data supplied using light can be displayed. Thus, a novel input/output device which is highly convenient or reliable can be provided.

One embodiment of the present invention is a method for driving the above input/output device, which includes the following steps.

A first step is to supply the selection signal capable of turning on the first transistor, the control signal capable of turning on the second transistor, and the display signal having a reference potential.

A second step is to supply the selection signal capable of turning off the first transistor and the control signal capable of turning on the second transistor, to supply the potential based on the high power supply potential so that the driving transistor supplies the predetermined current based on the sensing signal supplied by the sensing element, and to make the conversion circuit supply the sensing data based on the sensing signal.

A third step is to supply the selection signal capable of turning on the first transistor, the control signal capable of turning off the second transistor, and the display signal having a potential based on the display data.

A fourth step is to supply the selection signal capable of turning off the first transistor and the control signal capable of turning off the second transistor and to supply the potential based on the high power supply potential so that the driving transistor supplies the current based on the display signal supplied in the third step.

One embodiment of the present invention is a method for driving the above input/output device, which includes the following steps.

A first step is to supply the selection signal capable of turning off the first transistor and the fifth transistor, the first control signal capable of turning off the second transistor, the second control signal capable of turning on the third transistor, and the third control signal capable of turning off the fourth transistor.

A second step is to supply the selection signal capable of turning on the first transistor and the fifth transistor, the first control signal capable of turning off the second transistor, the second control signal capable of turning off the third transistor, the third control signal capable of turning off the fourth transistor, and the display signal having a reference potential.

A third step is to supply the selection signal capable of turning off the first transistor and the fifth transistor, the first control signal capable of turning on the second transistor, the second control signal capable of turning off the third transistor, and the third control signal capable of turning on the fourth transistor, to supply the potential based on the high power supply potential to the second wiring so that the driving transistor supplies the predetermined current based on the sensing signal supplied by the sensing element, and to make the conversion circuit supply the sensing data based on the sensing signal.

A fourth step is to supply the selection signal capable of turning off the first transistor and the fifth transistor, the first control signal capable of turning off the second transistor, the second control signal capable of turning on the third transistor, and the third control signal capable of turning off the fourth transistor.

A fifth step is to supply the selection signal capable of turning on the first transistor and the fifth transistor, the first control signal capable of turning off the second transistor, the second control signal capable of turning off the third transistor, the third control signal capable of turning off the fourth transistor, and the display signal based on the display data.

A sixth step is to supply the selection signal capable of turning off the first transistor and the fifth transistor, the first control signal capable of turning off the second transistor, the second control signal capable of turning on the third transistor, and the third control signal capable of turning on the fourth transistor and to supply the high power supply potential to the second wiring so that the driving transistor supplies the predetermined current based on the display signal supplied in the fifth step.

The driving method in one embodiment of the present invention includes the step of turning off the first transistor, turning on the second transistor, and setting a voltage between the gate and the second electrode of the driving transistor to a voltage between the first electrode and the second electrode of the sensing element.

Accordingly, the current supplied by the driving transistor or a voltage for supplying the predetermined current can be converted using the conversion circuit into the sensing data based on the sensing signal supplied by the sensing element, and the sensing data can be supplied. Thus, a novel method for driving an input/output device which is highly convenient or reliable can be provided.

One embodiment of the present invention includes a plurality of pixels arranged in a matrix.

Also included are a plurality of first control lines which are electrically connected to rows of the plurality of pixels and which are capable of supplying a selection signal, and a plurality of second control lines which are electrically connected to the rows of the plurality of pixels and which are capable of supplying a control signal.

Also included are a plurality of signal lines which are electrically connected to columns of the plurality of pixels and which are capable of supplying a display signal including display data, a plurality of first wirings which are electrically connected to the columns of the plurality of pixels and which are capable of supplying a first power supply potential, a plurality of second wirings which are electrically connected to the columns of the plurality of pixels and which are capable of supplying a potential based on a high power supply potential, and a plurality of third wirings which are electrically connected to the columns of the plurality of pixels and which are capable of supplying a second power supply potential.

Also included is a conversion circuit which is electrically connected to at least one of the plurality of second wirings, which is supplied with the high power supply potential, and which is capable of supplying the potential based on the high power supply potential and supplying sensing data based on a sensing signal.

Also included is a base which supports the pixels, the first control lines, the second control lines, the signal lines, and the first to third wirings.

Each of the pixels includes an input/output circuit supplied with the selection signal, the control signal, the display signal, and the sensing signal and capable of supplying a potential based on the sensing signal.

The pixel also includes a sensing element capable of supplying the sensing signal, and a display element supplied with a predetermined current.

The input/output circuit includes a first transistor. A gate of the first transistor is electrically connected to the first control line capable of supplying the selection signal. A first electrode of the first transistor is electrically connected to the signal line capable of supplying the display signal.

The input/output circuit includes a second transistor. A gate of the second transistor is electrically connected to the second control line capable of supplying the control signal. A first electrode of the second transistor is electrically connected to the first wiring.

The input/output circuit includes a driving transistor. A gate of the driving transistor is electrically connected to a second electrode of the first transistor. A first electrode of the driving transistor is electrically connected to the second wiring. A second electrode of the driving transistor is electrically connected to a second electrode of the second transistor.

The conversion circuit includes a transistor. A gate and a first electrode of the transistor are electrically connected to respective wirings each capable of supplying a high power supply potential. A second electrode of the transistor is electrically connected to the second wiring. The conversion circuit also includes a terminal electrically connected to the second wiring and capable of supplying the sensing data.

A first electrode of the sensing element is electrically connected to the second electrode of the first transistor. A second electrode of the sensing element is electrically connected to the second electrode of the second transistor.

A first electrode of the display element is electrically connected to the second electrode of the driving transistor. A second electrode of the display element is electrically connected to the third wiring.

One embodiment of the present invention includes a plurality of pixels arranged in a matrix.

Also included are a plurality of first control lines which are electrically connected to rows of the plurality of pixels and which are capable of supplying a selection signal, a plurality of second control lines which are electrically connected to the rows of the plurality of pixels and which are capable of supplying a first control signal, a plurality of third control lines which are electrically connected to the rows of the plurality of pixels and which are capable of supplying a second control signal, and a plurality of fourth control lines which are electrically connected to the rows of the plurality of pixels and which are capable of supplying a third control signal.

Also included are a plurality of signal lines which are electrically connected to columns of the plurality of pixels and which are capable of supplying a display signal including display data, a plurality of first wirings which are electrically connected to the columns of the plurality of pixels and which are capable of supplying a first power supply potential, a plurality of second wirings which are electrically connected to the columns of the plurality of pixels and which are capable of supplying a potential based on a high power supply potential, a plurality of third wirings which are electrically connected to the columns of the plurality of pixels and which are capable of supplying a second power supply potential, and a plurality of fourth wirings which are electrically connected to the columns of the plurality of pixels and which are capable of supplying a third power supply potential.

Also included is a conversion circuit which is electrically connected to at least one of the plurality of second wirings, which is supplied with the high power supply potential, and which is capable of supplying the potential based on the high power supply potential and supplying sensing data based on a sensing signal.

Also included is a base which supports the pixels, the first to fourth control lines, the signal lines, and the first to fourth wirings.

Each of the pixels includes an input/output circuit supplied with the selection signal, the first to third control signals, the display signal, and the sensing signal and capable of supplying a potential based on the sensing signal.

The pixel also includes a sensing element capable of supplying the sensing signal, and a display element supplied with a predetermined current.

The input/output circuit includes a first transistor. A gate of the first transistor is electrically connected to the first control line capable of supplying the selection signal. A first electrode of the first transistor is electrically connected to the signal line capable of supplying the display signal.

The input/output circuit includes a second transistor. A gate of the second transistor is electrically connected to the second control line capable of supplying the first control signal. A first electrode of the second transistor is electrically connected to the first wiring.

The input/output circuit includes a third transistor. A gate of the third transistor is electrically connected to the third control line capable of supplying the second control signal. A first electrode of the third transistor is electrically connected to a second electrode of the second transistor.

The input/output circuit includes a fourth transistor. A gate of the fourth transistor is electrically connected to the fourth control line capable of supplying the third control signal. A first electrode of the fourth transistor is electrically connected to a second electrode of the first transistor.

The input/output circuit includes a fifth transistor. A gate of the fifth transistor is electrically connected to the first control line capable of supplying the selection signal. A first electrode of the fifth transistor is electrically connected to a second electrode of the fourth transistor. A second electrode of the fifth transistor is electrically connected to the fourth wiring.

The input/output circuit includes a driving transistor. A gate of the driving transistor is electrically connected to the second electrode of the fourth transistor. A first electrode of the driving transistor is electrically connected to the second wiring. A second electrode of the driving transistor is electrically connected to the second electrode of the second transistor.

The conversion circuit includes a transistor. A gate and a first electrode of the transistor are electrically connected to respective wirings each capable of supplying a high power supply potential. A second electrode of the transistor is electrically connected to the second wiring. The conversion circuit also includes a terminal electrically connected to the second wiring and capable of supplying the sensing data.

A first electrode of the sensing element is electrically connected to the second electrode of the first transistor. A second electrode of the sensing element is electrically connected to the second electrode of the second transistor.

A first electrode of the display element is electrically connected to a second electrode of the third transistor. A second electrode of the display element is electrically connected to the third wiring.

In the above input/output device in one embodiment of the present invention, the sensing signal supplied by the sensing element may include a voltage which changes with a change in capacitance.

In the above input/output device in one embodiment of the present invention, the display element includes the first electrode, the second electrode overlapping with the first electrode, and a layer containing a light-emitting organic compound between the first electrode and the second electrode.

In the above input/output device in one embodiment of the present invention, the conversion circuit is supported by the base.

The input/output device in the above embodiment of the present invention includes the plurality of pixels each including the input/output circuit supplied with the selection signal, the control signal, the display signal including display data, and the sensing signal and capable of supplying the potential based on the sensing signal, the sensing element capable of supplying the sensing signal, and the display element supplied with a predetermined current, the base provided with the plurality of pixels arranged in a matrix, and the conversion circuit electrically connected to at least one of the columns of the pixels and capable of supplying the sensing data based on the sensing signal.

Accordingly, the sensing data which can be associated with data on the positions of the pixels arranged in a matrix can be supplied using a potential which changes in accordance with the sensing signal supplied by the sensing element included in each of the pixels. In addition, the display data can be displayed by the display element included in each of the pixels arranged in a matrix using the predetermined current based on the display signal. Thus, a novel input/output device which is highly convenient or reliable can be provided.

Note that in this specification, an EL layer refers to a layer provided between a pair of electrodes in a light-emitting element. Thus, a light-emitting layer containing an organic compound that is a light-emitting substance which is provided between electrodes is one embodiment of the EL layer.

In this specification, in the case where a substance A is dispersed in a matrix formed using a substance B, the substance B forming the matrix is referred to as a host material, and the substance A dispersed in the matrix is referred to as a guest material. Note that the substance A and the substance B may each be a single substance or a mixture of two or more kinds of substances.

Note that a light-emitting device in this specification means an image display device or a light source (including a lighting device). In addition, the light-emitting device includes any of the following modules in its category: a module in which a connector such as a flexible printed circuit (FPC) or a tape carrier package (TCP) is attached to a light-emitting device; a module having a TCP provided with a printed wiring board at the end thereof; and a module having an integrated circuit (IC) directly mounted on a substrate over which a light-emitting element is formed, by a chip on glass (COG) method.

Although a block diagram attached to this specification shows elements classified according to their functions in independent blocks, it may be practically difficult to completely separate the elements according to their functions and, in some cases, one element may be involved in a plurality of functions.

In this specification, the terms “source” and “drain” of a transistor interchange with each other depending on the polarity of the transistor or levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, although connection relation of the transistor is described assuming that the source and the drain are fixed for convenience in some cases, actually, the names of the source and the drain interchange with each other depending on the relation of the potentials.

A “source” of a transistor in this specification means a source region that is part of a semiconductor film functioning as an active layer or a source electrode connected to the semiconductor film. Similarly, a “drain” of a transistor means a drain region that is part of the semiconductor film or a drain electrode connected to the semiconductor film. A “gate” means a gate electrode.

In this specification, a state in which first and second transistors are connected to each other in series means, for example, a state in which only one of a source and a drain of the first transistor is connected to only one of a source and a drain of the second transistor. In addition, a state in which first and second transistors are connected to each other in parallel means a state in which one of a source and a drain of the first transistor is connected to one of a source and a drain of the second transistor and the other of the source and the drain of the first transistor is connected to the other of the source and the drain of the second transistor.

The term “connection” in this specification refers to electrical connection and corresponds to a state in which current, voltage, or a potential can be supplied or transmitted. Accordingly, a state of being connected means not only a state of direct connection but also a state of electrical connection through a circuit element such as a wiring, a resistor, a diode, or a transistor so that current, voltage, or a potential can be supplied or transmitted.

In this specification, even when different components are connected to each other in a circuit diagram, there is actually a case where one conductive film has functions of a plurality of components such as a case where part of a wiring functions also as an electrode. The term “connection” in this specification also means such a case where one conductive film has functions of a plurality of components.

Furthermore, in this specification, one of a first electrode and a second electrode of a transistor refers to a source electrode and the other refers to a drain electrode.

According to one embodiment of the present invention, a novel input/output device which is highly convenient or reliable can be provided. Alternatively, a novel method for driving an input/output device which is highly convenient or reliable can be provided. Alternatively, a novel semiconductor device can be provided.

Note that the descriptions of these effects do not disturb the existence of other effects. One embodiment of the present invention does not necessarily achieve all the above effects. Other effects will be apparent from and can be derived from the descriptions of the specification, the drawings, the claims, and the like.

### BRIEF DESCRIPTION OF DRAWINGS

FIGS. 1A and 1B are a circuit diagram illustrating a structure of an input/output device according to one embodiment and a timing chart illustrating a driving method thereof.

FIGS. 2A and 2B are a circuit diagram illustrating a structure of an input/output device according to one embodiment and a timing chart illustrating a driving method thereof.

FIGS. 3A and 3B are a block diagram and a circuit diagram illustrating a structure of an input/output device according to one embodiment.

FIG. 4 is a circuit diagram illustrating a structure of an input/output device according to one embodiment.

FIGS. 5A1, 5A2, 5B1, and 5B2 are timing charts illustrating a method for driving an input/output device according to one embodiment.

FIGS. 6A to 6D are a top view and cross-sectional views illustrating a structure of an input/output device according to one embodiment.

FIGS. 7A to 7C illustrate a structure of a transistor that can be used in a conversion circuit according to one embodiment.

FIGS. 8A1, 8A2, 8B1, 8B2, 8C, 8D1, 8D2, 8E1, and 8E2 are schematic views illustrating a manufacturing process of a stack body according to one embodiment.

FIGS. 9A1, 9A2, 9B1, 9B2, 9C, 9D1, 9D2, 9E1, and 9E2 are schematic views illustrating a manufacturing process of a stack body according to one embodiment.

FIGS. 10A1, 10A2, 10B, 10C, 10D1, 10D2, 10E1, and 10E2 are schematic views illustrating a manufacturing process of a stack body according to one embodiment.

FIGS. 11A1, 11A2, 11B1, 11B2, 11C1, 11C2, 11D1, and 11D2 are schematic views illustrating a manufacturing process of a stack body having an opening portion in a support body according to one embodiment.

FIGS. 12A1, 12A2, 12B 1, and 12B2 are schematic views each illustrating a structure of a process member according to one embodiment.

FIGS. 13A to 13C are projection views illustrating a structure of a data processing device according to one embodiment.

FIGS. 14A to 14D are a top view and cross-sectional views illustrating a structure of an input/output device according to one embodiment.

### BEST MODE FOR CARRYING OUT THE INVENTION

An input/output device in one embodiment of the present invention includes an input/output circuit supplied with a selection signal, a control signal, a display signal including display data, and a sensing signal and capable of supplying a potential based on the sensing signal, a conversion circuit capable of supplying sensing data based on the sensing signal, a sensing element capable of supplying the sensing signal, and a display element supplied with a predetermined current.

Accordingly, the sensing data can be supplied using a potential which changes in accordance with the sensing signal supplied by the sensing element, and the display data can be displayed by the display element using the predetermined current based on the display signal. Thus, a novel input/output device which is highly convenient or reliable can be provided. Alternatively, a method for driving an input/output device can be provided.

Embodiments will be described in detail with reference to the drawings. Note that the present invention is not limited to the following description, and it will be easily understood by those skilled in the art that various changes and modifications can be made without departing from the spirit and scope of the present invention. Therefore, the present invention should not be construed as being limited to the description in the following embodiments. Note that in the structures of the invention described below, the same portions or portions having similar functions are denoted by the same reference numerals in different drawings, and description of such portions is not repeated.

### Embodiment 1

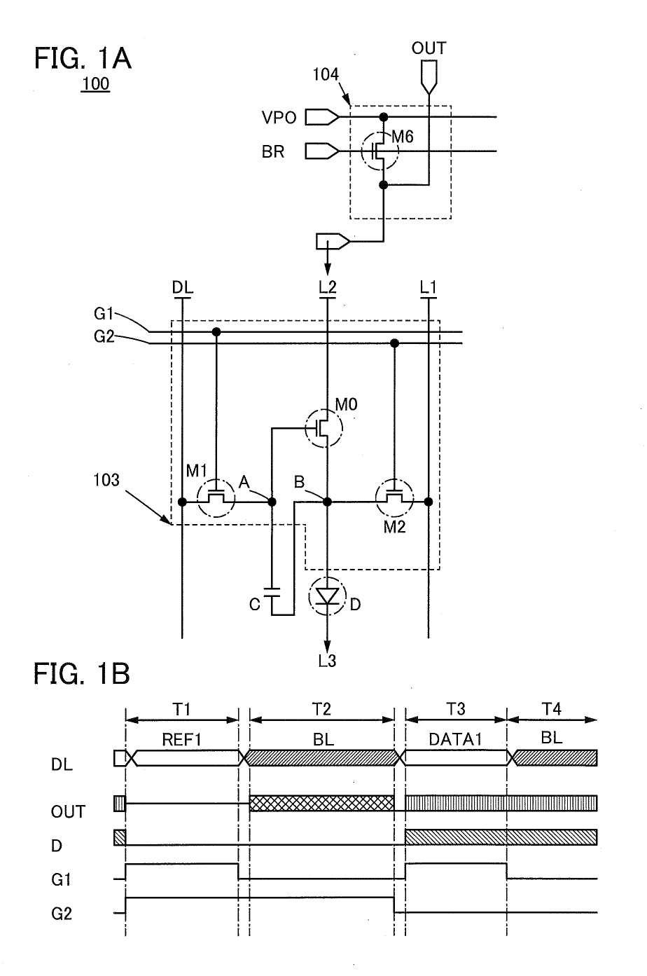

In this embodiment, a structure of an input/output device in one embodiment of the present invention will be described with reference to FIGS. 1A and 1B.

FIGS. 1A and 1B illustrate a structure of an input/output device 100 in one embodiment of the present invention. FIG. 1A is a circuit diagram illustrating a structure of the input/output device of one embodiment of the present invention. FIG. 1B is a timing chart illustrating a method for driving the input/output device illustrated in FIG. 1A.

### <Structure Example of Input/Output Device>

The input/output device 100 described in this embodiment includes an input/output circuit 103 supplied with a selection signal, a control signal, a display signal including display data, and a sensing signal and capable of supplying a potential based on the sensing signal.

The input/output device 100 also includes a conversion circuit 104 supplied with a high power supply potential and capable of supplying a potential based on the high power supply potential and supplying sensing data based on the sensing signal.

The input/output device 100 also includes a sensing element C capable of supplying the sensing signal, and a display element D supplied with a predetermined current.

The input/output circuit 103 includes a first transistor M1. A gate of the first transistor M1 is electrically connected to a first control line G1 capable of supplying the selection signal. A first electrode of the first transistor M1 is electrically connected to a signal line DL capable of supplying the display signal.

The input/output circuit 103 includes a second transistor M2. A gate of the second transistor M2 is electrically connected to a second control line G2 capable of supplying the control signal. A first electrode of the second transistor M2 is electrically connected to a first wiring L1.

The input/output circuit 103 includes a driving transistor M0. A gate of the driving transistor M0 is electrically connected to a second electrode of the first transistor M1. A first electrode of the driving transistor M0 is electrically connected to a second wiring L2. A second electrode of the driving transistor M0 is electrically connected to a second electrode of the second transistor M2.

The conversion circuit 104 includes a transistor M6. A gate of the transistor M6 is electrically connected to a wiring BR capable of supplying a high power supply potential. A first electrode of the transistor M6 is electrically connected to a wiring VPO capable of supplying the high power supply potential. A second electrode of the transistor M6 is electrically connected to the second wiring L2. The conversion circuit 104 also includes a terminal OUT electrically connected to the second wiring L2 and capable of supplying the sensing data.

A first electrode of the sensing element C is electrically connected to the second electrode of the first transistor M1. A second electrode of the sensing element C is electrically connected to the second electrode of the second transistor M2.

A first electrode of the display element D is electrically connected to the second electrode of the driving transistor M0. A second electrode of the display element D is electrically connected to a third wiring L3.

The input/output device 100 described as an example in this embodiment includes the input/output circuit 103 supplied with the selection signal, the control signal, the display signal including display data, and the sensing signal and capable of supplying the potential based on the sensing signal, the conversion circuit 104 capable of supplying the sensing data based on the sensing signal, the sensing element C capable of supplying the sensing signal, and the display element D supplied with the predetermined current.

Accordingly, the sensing data can be supplied using a potential which changes in accordance with the sensing signal supplied by the sensing element, and the display data can be displayed by the display element using the predetermined current based on the display signal. Thus, a novel input/output device which is highly convenient or reliable can be provided.

Note that the driving transistor M0 can amplify the sensing signal supplied by the sensing element C.

Note that the wiring VPO and the wiring BR can each supply a power supply potential high enough to operate a transistor included in the input/output device 100.

The first wiring L1 can supply a first power supply potential, and the third wiring L3 can supply a second power supply potential. Note that the second power supply potential is preferably higher than the first power supply potential.

Individual components included in the input/output device 100 will be described below.

Note that in some cases, these components cannot be clearly distinguished and one component may serve also as another component or include part of another component.

For example, an input/output circuit electrically connected to a sensing element and a display element serves as a driver circuit for the sensing element and also as a driver circuit for the display element.

### <<Entire Structure>>

The input/output device 100 includes the input/output circuit 103, the conversion circuit 104, the sensing element C, or the display element D.

### <<Input/Output Circuit>>

The input/output circuit 103 includes the first transistor M1, the second transistor M2, or the driving transistor M0. Note that the driving transistor may drive the display element using a time division grayscale method (also referred to as a digital driving method) or may drive the display element using a current grayscale method (also referred to as an analog driving method).

Transistors which can be manufactured through the same process can be used as the first transistor M1, the second transistor M2, and the driving transistor M0. Accordingly, the input/output circuit can be provided through a simplified manufacturing process.

Note that a switch which can be turned on or off in accordance with the selection signal can be used instead of the first transistor M1.

A switch which can be turned on or off in accordance with the control signal can be used instead of the second transistor M2.

The first transistor M1, the second transistor M2, or the driving transistor M0 includes a semiconductor layer.

For example, for the semiconductor layer, a Group 4 element, a compound semiconductor, or an oxide semiconductor can be used. Specifically, a semiconductor containing silicon, a semiconductor containing gallium arsenide, an oxide semiconductor containing indium, or the like can be used for the semiconductor layer. A semiconductor such as a single crystal, polycrystalline, or amorphous semiconductor, specifically, single crystal silicon, polysilicon, amorphous silicon, or the like can be used.

Note that a structure of a transistor in which an oxide semiconductor is used for the semiconductor layer is described in detail in Embodiment 5.

The input/output circuit 103 is electrically connected to the first control line G1, the second control line G2, the signal line DL, the first wiring L1, the second wiring L2, or the third wiring L3.

The first control line G1 can supply the selection signal.

The second control line G2 can supply the control signal.

The signal line DL can supply the display signal.

The first wiring L1 can supply the first power supply potential.

The second wiring L2 can supply the potential based on the high power supply potential.

The third wiring L3 can supply the second power supply potential.

A conductive material is used for the first control line G1, the second control line G2, the signal line DL, the first wiring L1, the second wiring L2, the third wiring L3, or the like.

For example, an inorganic conductive material, an organic conductive material, a metal, a conductive ceramic, or the like can be used for the wiring.

Specifically, a metal element selected from aluminum, gold, platinum, silver, chromium, tantalum, titanium, molybdenum, tungsten, nickel, iron, cobalt, palladium, and manganese; an alloy including any of the above-described metal elements; an alloy including any of the above-described metal elements in combination; or the like can be used for the wiring or the like.

Alternatively, a conductive oxide such as indium oxide, indium tin oxide, indium zinc oxide, zinc oxide, or zinc oxide to which gallium is added can be used.

Alternatively, graphene or graphite can be used. A film containing graphene can be formed, for example, by reducing a film containing graphene oxide. As a reducing method, a method with application of heat, a method using a reducing agent, or the like can be given.

Alternatively, a conductive high molecule can be used.

Note that the input/output circuit 103 may be formed using a method in which films used to form the input/output circuit 103 are formed over a base for supporting the input/output circuit 103 and are then processed.

Alternatively, the input/output circuit 103 may be formed using a method in which the input/output circuit 103 formed over a base is transferred to another base for supporting the input/output circuit 103. An example of a method for manufacturing the input/output circuit 103 will be described in detail in Embodiments 6 to 8.

### <<Conversion Circuit>>

A variety of circuits which can supply the terminal OUT with the potential based on the high power supply potential and sensing data based on the amount of a current flowing through the first wiring L1 can be used as the conversion circuit 104.

For example, a circuit which forms a source follower circuit, a current mirror circuit, or the like by being electrically connected to the input/output circuit 103 can be used as the conversion circuit 104.

Specifically, a circuit including the transistor M6 whose gate is electrically connected to the wiring BR, whose first electrode is electrically connected to the wiring VPO, and whose second electrode is electrically connected to the second wiring L2 can be used as the conversion circuit 104.

For example, a source follower circuit can be formed by the conversion circuit 104 and the input/output circuit 103 (see FIG. 1A) when a power supply potential high enough to drive a transistor is supplied to each of the wiring VPO and the wiring BR.

A transistor having a structure similar to that of a transistor which can be used in the input/output circuit 103 can be used as the transistor M6.

Wirings similar to a wiring which can be used in the input/output circuit 103 can be used as the wiring VPO and the wiring BR.

Note that the conversion circuit 104 may be supported using the base for supporting the input/output circuit 103.

The conversion circuit 104 may be formed through the same process as the input/output circuit 103.

### <<Sensing Element>>

The sensing element C senses, for example, capacitance, illuminance, magnetic force, electric waves, pressure, or the like and supplies a voltage based on the sensed physical quantity to the first electrode and the second electrode.

For example, a capacitor, a photoelectric conversion element, a magnetic sensing element, a piezoelectric element, a resonator, or the like can be used as the sensing element.

Specifically, a sensing element which supplies a sensing signal including a voltage that changes with a change in capacitance can be used as the sensing element C. When an object having a dielectric constant higher than that of the air, such as a finger, is located close to a conductive film in the air, for example, the capacitance between the object and the conductive film changes. A sensing signal can be supplied by sensing this capacitance change. Specifically, a capacitor including a conductive film which is connected to one of electrodes can be used as the sensing element C. The change in capacitance causes charge distribution, leading to a change in voltage between both electrodes of the capacitor. This voltage change can be used as the sensing signal.

### <<Display Element>>

The display element D is supplied with a current based on the display signal and displays the display data.

For example, an organic electroluminescent element, a light-emitting diode, or the like can be used as the display element D.

Specifically, a light-emitting element which includes a first electrode, a second electrode overlapping with the first electrode, and a layer containing a light-emitting organic compound between the first electrode and the second electrode (referred to as an organic electroluminescent element or an organic EL element) can be used as the display element D.

### <Method for Driving Input/Output Device>

A method for driving the input/output device 100 in which the sensing data based on the voltage supplied by the sensing element C is supplied and display is performed in accordance with the supplied display signal will be described (see FIGS. 1A and 1B).

### <<First Step>>

In a first step, the selection signal capable of turning on the first transistor M1 is supplied, the control signal capable of turning on the second transistor M2 is supplied, and the display signal having a reference potential is supplied (see a period T1 in FIG. 1B).

Accordingly, the potential of a node A electrically connected to the second electrode of the first transistor M1, the gate of the driving transistor M0, and the first electrode of the sensing element C can be reset to a potential based on the reference potential supplied by the signal line DL.

In addition, the potential of a node B electrically connected to the second electrode of the second transistor M2, the second electrode of the driving transistor M0, the first electrode of the display element D, and the second electrode of the sensing element C can be set to a potential based on the first power supply potential supplied by the first wiring L1.

### <<Second Step>>

The selection signal capable of turning off the first transistor M1 is supplied, the control signal capable of turning on the second transistor M2 is supplied, the potential based on the high power supply potential is supplied so that the driving transistor M0 supplies the predetermined current, and the conversion circuit supplies the sensing data based on the sensing signal (see a period T2 in FIG. 1B).

Accordingly, the potential of the node A can be set to the potential based on the sensing signal supplied by the sensing element C.

In addition, the driving transistor M0 whose gate is supplied with the potential of the node A supplies the predetermined current from the second wiring L2 to the first wiring L1 depending on the potential of the node A.

The conversion circuit 104 supplies the terminal OUT with the sensing data based on a current or a voltage necessary for supplying the predetermined current to the second wiring L2. Note that a difference between a current flowing through the second wiring L2 in a state where an object having a dielectric constant higher than that of the air, such as a finger, is sensed by the sensing element C and that in a state where the object is not sensed may be used as the sensing data. Alternatively, a difference between a voltage necessary for supplying the predetermined current to the second wiring L2 in a state where an object having a dielectric constant higher than that of the air, such as a finger, is sensed by the sensing element C and that in a state where the object is not sensed may be used as the sensing data. Alternatively, sensing data may be repeatedly obtained, and a difference from the records may be used.

### <<Third Step>>

The selection signal capable of turning on the first transistor M1 is supplied, the control signal capable of turning off the second transistor M2 is supplied, and the display signal having a potential based on the display data is supplied (see a period T3 in FIG. 1B).

Accordingly, the potential of the node A can be set to the potential based on the display signal supplied by the signal line DL.

In addition, the driving transistor M0 whose gate is supplied with the potential of the node A supplies the predetermined current from the second wiring L2 to the display element D depending on the potential of the node A.

### <<Fourth Step>>

The selection signal capable of turning off the first transistor M1 is supplied, the control signal capable of turning off the second transistor M2, and the potential based on the high power supply potential is supplied so that the driving transistor M0 supplies the predetermined current based on the display signal supplied in the third step (see a period T4 in FIG. 1B).

Accordingly, the potential of the node A is kept at the potential based on the display signal supplied by the signal line DL, and the driving transistor M0 whose gate is supplied with the potential of the node A supplies the predetermined current based on the display signal to the display element D.

Note that even in the case where the display data is displayed, the potential of the node A may be changed when a finger or the like is located close to the sensing element C. However, a change in display by the display element D due to the change in the potential of the node A is obscured by the finger or the like and is unlikely to be visually recognized by a user.

The method for driving the input/output device 100 described in this embodiment includes the step of turning off the first transistor M1, turning on the second transistor M2, and setting a voltage between the gate and the second electrode of the driving transistor M0 to a voltage between the first electrode and the second electrode of the sensing element C.

Accordingly, a current supplied by the driving transistor M0 or a voltage for supplying the predetermined current can be converted using the conversion circuit 104 into the sensing data based on the sensing signal supplied by the sensing element C, and the sensing data can be supplied. Thus, a novel method for driving an input/output device which is highly convenient or reliable can be provided.

Note that this embodiment can be combined with any of the other embodiments in this specification as appropriate.

### Embodiment 2

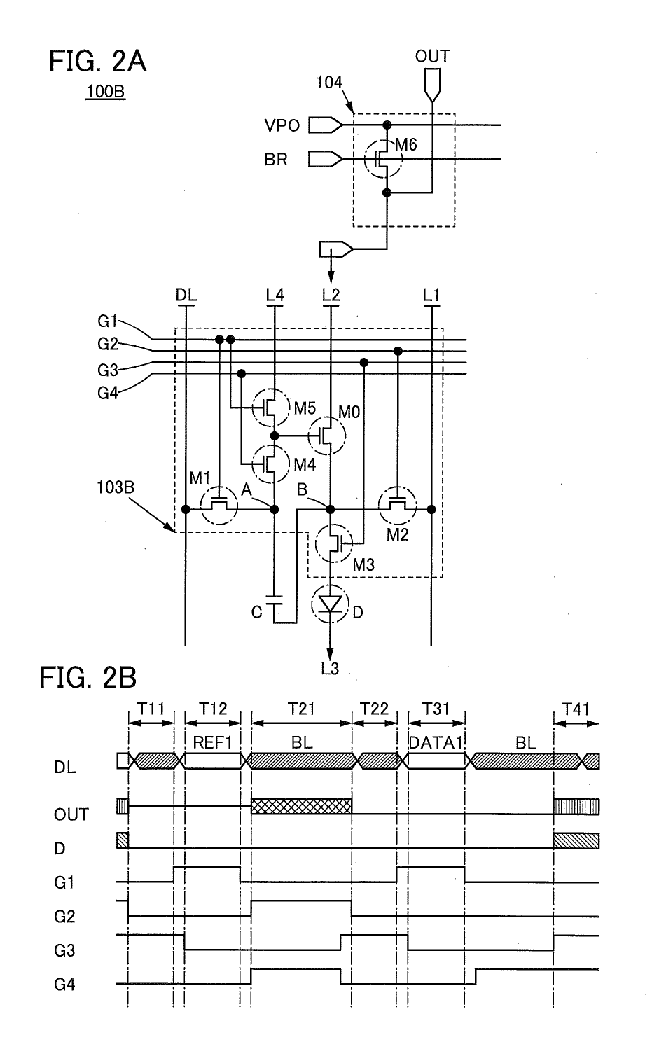

In this embodiment, a structure of an input/output device in one embodiment of the present invention will be described with reference to FIGS. 2A and 2B.

FIGS. 2A and 2B illustrate a structure of an input/output device 100B in one embodiment of the present invention. FIG. 2A is a circuit diagram illustrating a structure of the input/output device in one embodiment of the present invention. FIG. 2B is a timing chart for illustrating a method for driving the input/output device illustrated in FIG. 2A.

### <Structure Example of Input/Output Device>

The input/output device 100B described in this embodiment includes an input/output circuit 103B supplied with a selection signal, first to third control signals, a display signal including display data, and a sensing signal and capable of supplying a potential based on the sensing signal.

The input/output device 100B also includes a conversion circuit 104 supplied with a high power supply potential and capable of supplying a potential based on the high power supply potential and supplying sensing data based on the sensing signal.

The input/output device 100B also includes a sensing element C capable of supplying the sensing signal, and a display element D supplied with a predetermined current.

The input/output circuit 103B includes a first transistor M1. A gate of the first transistor M1 is electrically connected to a first control line G1 capable of supplying the selection signal. A first electrode of the first transistor M1 is electrically connected to a signal line DL capable of supplying the display signal.

The input/output circuit 103B includes a second transistor M2. A gate of the second transistor M2 is electrically connected to a second control line G2 capable of supplying the first control signal. A first electrode of the second transistor M2 is electrically connected to a first wiring L1.

The input/output circuit 103B includes a third transistor M3. A gate of the third transistor M3 is electrically connected to a third control line G3 capable of supplying the second control signal. A first electrode of the third transistor M3 is electrically connected to a second electrode of the second transistor M2.

The input/output circuit 103B includes a fourth transistor M4. A gate of the fourth transistor M4 is electrically connected to a fourth control line G4 capable of supplying the third control signal. A first electrode of the fourth transistor M4 is electrically connected to a second electrode of the first transistor M1.

The input/output circuit 103B includes a fifth transistor M5. A gate of the fifth transistor M5 is electrically connected to the first control line G1 capable of supplying the selection signal. A first electrode of the fifth transistor M5 is electrically connected to a second electrode of the fourth transistor M4. A second electrode of the fifth transistor M5 is electrically connected to a fourth wiring L4.

The input/output circuit 103B includes a driving transistor M0. A gate of the driving transistor M0 is electrically connected to the second electrode of the fourth transistor M4. A first electrode of the driving transistor M0 is electrically connected to a second wiring L2. A second electrode of the driving transistor M0 is electrically connected to the second electrode of the second transistor M2.

The conversion circuit 104 includes a transistor M6. A gate of the transistor M6 is electrically connected to a wiring BR capable of supplying a high power supply potential. A first electrode of the transistor M6 is electrically connected to a wiring VPO capable of supplying the high power supply potential. A second electrode of the transistor M6 is electrically connected to the second wiring L2. The conversion circuit 104 also includes a terminal OUT electrically connected to the second wiring L2 and capable of supplying the sensing data.

A first electrode of the sensing element C is electrically connected to the second electrode of the first transistor M1. A second electrode of the sensing element C is electrically connected to the second electrode of the second transistor M2.

A first electrode of the display element D is electrically connected to a second electrode of the third transistor M3. A second electrode of the display element D is electrically connected to a third wiring L3.

The input/output device 100B described as an example in this embodiment includes the input/output circuit 103B supplied with the selection signal, the control signals, the display signal including display data, and the sensing signal and capable of supplying the potential based on the sensing signal, the conversion circuit 104 capable of supplying the sensing data based on the sensing signal, the sensing element C capable of supplying the sensing signal, and the display element D supplied with the predetermined current.

Accordingly, the sensing data can be supplied using a potential which changes in accordance with the sensing signal supplied by the sensing element, and the display data can be displayed by the display element using the predetermined current which changes in accordance with the display signal. Thus, a novel input/output device which is highly convenient or reliable can be provided.

Note that the wiring VPO and the wiring BR can each supply a power supply potential high enough to operate a transistor included in the input/output device 100B.

The first wiring L1 can supply a first power supply potential, the third wiring L3 can supply a second power supply potential, and the fourth wiring L4 can supply a third power supply potential. Note that the second power supply potential is preferably higher than the first power supply potential. The third power supply potential is preferably higher than the first power supply potential and the second power supply potential and lower than a high-level potential of the first control signal. Specifically, the first power supply potential can be −5 V, the second power supply potential can be −3 V, the third power supply potential can be +6 V, and the high-level potential of the first control signal can be +15 V.

Individual components included in the input/output device 100B will be described below. Note that in some cases, these components cannot be clearly distinguished and one component may serve also as another component or include part of another component.

For example, an input/output circuit electrically connected to a sensing element and a display element serves as a driver circuit for the sensing element and also as a driver circuit for the display element.

The input/output device 100B differs from the input/output device 100 described with reference to FIGS. 1A and 1B in that the input/output circuit 103B includes the third to fifth transistors M3 to M5 and is electrically connected to the third control line G3 and the fourth control line G4. Different components are described in detail below, and the above description is referred to for the other similar components.

### <<Entire Structure>>

The input/output device 100B includes the input/output circuit 103B, the conversion circuit 104, the sensing element C, or the display element D.

### <<Input/Output Circuit>>

The input/output circuit 103B includes the first to fifth transistors M1 to M5 or the driving transistor M0.

Transistors which can be manufactured through the same process can be used as the first to fifth transistors M1 to M5 and the driving transistor M0. Accordingly, the input/output circuit can be provided through a simplified manufacturing process.

Note that a switch which can be turned on or off in accordance with the selection signal can be used instead of the first transistor M1 or the fifth transistor M5.

A switch which can be turned on or off in accordance with the first control signal can be used instead of the second transistor M2.

A switch which can be turned on or off in accordance with the second control signal can be used instead of the third transistor M3.

A switch which can be turned on or off in accordance with the third control signal can be used instead of the fourth transistor M4.

Any of the first to fifth transistors M1 to M5 or the driving transistor M0 includes a semiconductor layer.

For example, transistors similar to transistors which can be used in the input/output device 100 described in Embodiment 1 can be used as the transistors in the input/output device 100B.

The input/output circuit 103B is electrically connected to the first to fourth control lines G1 to G4, the signal line DL, or the first to fourth wirings L1 to L4.

The first control line G1 can supply the selection signal.

The second control line G2 can supply the first selection signal. The third control line G3 can supply the second control signal. The fourth control line G4 can supply the third control signal.

The signal line DL can supply the display signal.

The first wiring L1 can supply the first power supply potential.

The second wiring L2 can supply the potential based on the high power supply potential.

The third wiring L3 can supply the second power supply potential.

The fourth wiring L4 can supply the third power supply potential.

For example, wirings similar to wirings which can be used in the input/output device 100 described in Embodiment 1 can be used as the wirings in the input/output device 100B.

### <Method for Driving Input/Output Device>

A method for driving the input/output device 100B in which the sensing data based on the voltage supplied by the sensing element C is supplied and display is performed in accordance with the supplied display signal will be described (see FIGS. 2A and 2B).

### <<First Step>>

In a first step, the selection signal capable of turning off the first transistor M1 and the fifth transistor M5, the first control signal capable of turning off the second transistor M2, the second control signal capable of turning on the third transistor M3, and the third control signal capable of turning off the fourth transistor M4 are supplied (see a period T11 in FIG. 2B).

Accordingly, the potential of a node B electrically connected to the second electrode of the second transistor M2, the first electrode of the third transistor M3, the second electrode of the driving transistor M0, and the second electrode of the sensing element C can be set to a potential higher than the second power supply potential by a voltage which determines whether the display element D operates or not (also referred to as threshold voltage). As a result, the potential of the node B which changes in and after a second step can be set to a potential based on the threshold voltage of the display element D. Even in the case where the threshold voltage Vₜₕ of the driving transistor M0 is shifted in the positive direction, for example, the driving transistor M0 can be turned on in accordance with the selection signal.

### <<Second Step>>

In a second step, the selection signal capable of turning on the first transistor M1 and the fifth transistor M5, the first control signal capable of turning off the second transistor M2, the second control signal capable of turning off the third transistor M3, the third control signal capable of turning off the fourth transistor M4, and the display signal having a reference potential are supplied (see a period T12 in FIG. 2B).

Accordingly, the potential of a node A electrically connected to the second electrode of the first transistor M1, the first electrode of the fourth transistor M4, the first electrode of the sensing element C can be reset to a potential based on the reference potential supplied by the signal line DL.

In addition, the potential of the gate of the driving transistor M0 can be reset to a potential based on the third power supply potential supplied by the fourth wiring L4.

### <<Third Step>>

In a third step, the selection signal capable of turning off the first transistor M1 and the fifth transistor M5, the first control signal capable of turning on the second transistor M2, the second control signal capable of turning off the third transistor M3, and the third control signal capable of turning on the fourth transistor M4 are supplied, the potential based on the high power supply potential is supplied to the second wiring L2 so that the driving transistor M0 supplies the predetermined current based on the sensing signal supplied by the sensing element C, and the conversion circuit 104 supplies the sensing data based on the sensing signal (see a period T21 in FIG. 2B).

Accordingly, the potential of the node B can be set to a potential based on the first power supply potential supplied by the first wiring L1.

Accordingly, the potential of the node A can be set to the potential based on the sensing signal supplied by the sensing element C.

In addition, the driving transistor M0 whose gate is supplied with the potential of the node A supplies the predetermined current from the second wiring L2 to the first wiring L1 depending on the potential of the node A.

The conversion circuit 104 supplies the terminal OUT with the sensing data based on the predetermined current flowing through the second wiring L2.

### <<Fourth Step>>

In a fourth step, the selection signal capable of turning off the first transistor M1 and the fifth transistor M5, the first control signal capable of turning off the second transistor M2, the second control signal capable of turning on the third transistor M3, and the third control signal capable of turning off the fourth transistor M4 are supplied (see a period T22 in FIG. 2B).

Accordingly, the potential of the node B can be set to a potential higher than the second power supply potential by a potential which determines whether the display element D operates or not (also referred to as threshold potential). As a result, the potential of the node B which changes in and after a fifth step can be set to a potential based on the threshold voltage of the display element D. Even in the case where the threshold voltage Vₜₕ of the driving transistor M0 is shifted in the positive direction, for example, the driving transistor M0 can be turned on in accordance with the selection signal.

### <<Fifth Step>>

In a fifth step, the selection signal capable of turning on the first transistor M1 and the fifth transistor M5, the first control signal capable of turning off the second transistor M2, the second control signal capable of turning off the third transistor M3, the third control signal capable of turning off the fourth transistor M4, and the display signal based on the display data are supplied (see a period T31 in FIG. 2B).

Accordingly, the potential of the node A can be set to the potential based on the display signal supplied by the signal line DL.

In addition, the potential of the gate of the driving transistor M0 can be reset to the potential based on the third power supply potential supplied by the fourth wiring L4.

### <<Sixth Step>>

In a sixth step, the selection signal capable of turning off the first transistor M1 and the fifth transistor M5, the first control signal capable of turning off the second transistor M2, the second control signal capable of turning on the third transistor M3, and the third control signal capable of turning on the fourth transistor M4 are supplied, and the high power supply potential is supplied to the second wiring L2 so that the driving transistor M0 supplies the predetermined current based on the display signal supplied in the fifth step (see a period T41 in FIG. 2B).

Accordingly, the driving transistor M0 whose gate is supplied with the potential based on the display signal supplied in the fifth step supplies the predetermined current to the display element D through the third transistor M3, and the display element D performs display in accordance with the display signal.

The method for driving the input/output device 100B described in this embodiment includes the step of turning off the first transistor M1, turning on the second transistor M2, and setting a voltage between the gate and the second electrode of the driving transistor M0 to a voltage between the first electrode and the second electrode of the sensing element C.

Accordingly, a current supplied by the driving transistor M0 or a voltage for supplying the predetermined current can be converted using the conversion circuit 104 into the sensing data based on the sensing signal supplied by the sensing element C, and the sensing data can be supplied. Thus, a novel method for driving an input/output device which is highly convenient or reliable can be provided.

Note that this embodiment can be combined with any of the other embodiments in this specification as appropriate.

### Embodiment 3

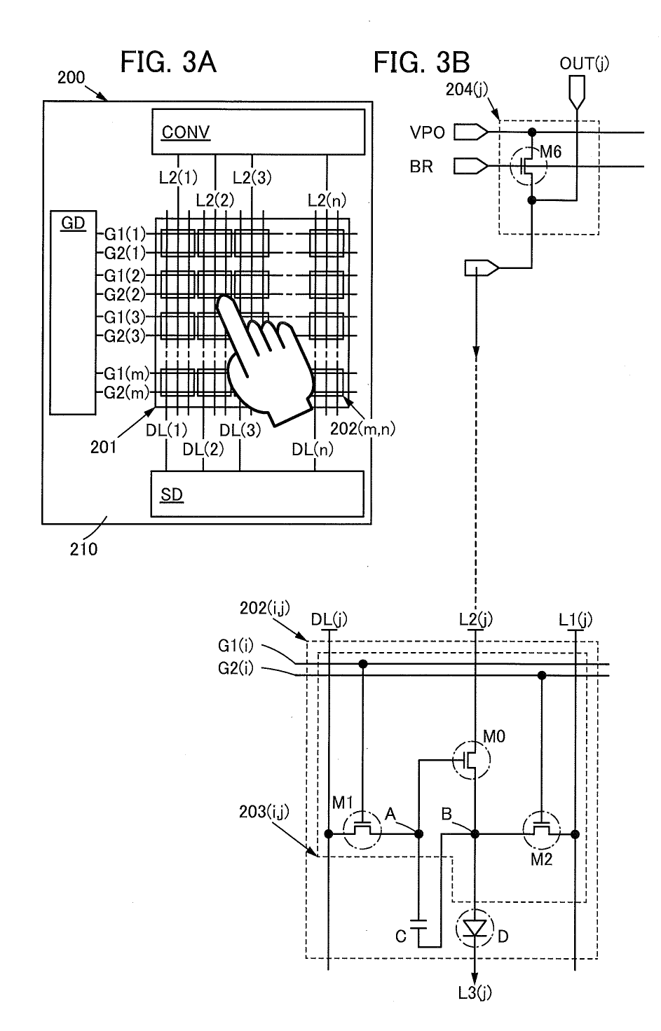

In this embodiment, a structure of an input/output device of one embodiment of the present invention will be described with reference to FIGS. 3A and 3B.

FIGS. 3A and 3B illustrate a structure of an input/output device 200 of one embodiment of the present invention. FIG. 3A is a block diagram illustrating a structure of the input/output device 200 of one embodiment of the present invention. FIG. 3B is a circuit diagram of an input/output circuit 203(i,j) included in a pixel 202(i,j) illustrated in FIG. 3A and a circuit diagram of a conversion circuit 204(j) included in a converter CONV.

### <Structure Example 1 of Input/Output Device>

The input/output device 200 described in this embodiment includes a region 201. The region 201 includes a plurality of pixels 202(i,j) arranged in a matrix of in rows and n columns. Note that in and n are each a natural number greater than or equal to 1, and m or n is greater than or equal to 2. In addition, i is less than or equal to m, and j is less than or equal to n.

The input/output device 200 also includes a plurality of first control lines G1(i) which are electrically connected to rows of the plurality of pixels 202(i,j) and which are capable of supplying a selection signal, and a plurality of second control lines G2(i) which are electrically connected to the rows of the plurality of pixels 202(i,j) and which are capable of supplying a control signal.

The input/output device 200 also includes a plurality of signal lines DL(j) which are electrically connected to columns of the plurality of pixels 202(i,j) and which are capable of supplying a display signal including display data, a plurality of first wirings L1(j) which are electrically connected to the columns of the plurality of pixels 202(i,j) and which are capable of supplying a first power supply potential, a plurality of second wirings L2(j) which are electrically connected to the columns of the plurality of pixels 202(i,j) and which are capable of supplying a potential based on a high power supply potential, and a plurality of third wirings L3(j) which are electrically connected to the columns of the plurality of pixels 202(i,j) and which are capable of supplying a second power supply potential.

The input/output device 200 also includes a conversion circuit 204(j) which is electrically connected to one of the plurality of second wirings L2(j), which is supplied with the high power supply potential, and which is capable of supplying a potential based on the high power supply potential and supplying sensing data based on a sensing signal.

The input/output device 200 also includes a base 210 which supports the pixels 202(0, the first control lines G1(i), the second control lines G2(i), the signal lines DL(i), and the first to third wirings L1(j) to L3(j).

Each of the pixels 202(i,j) includes the input/output circuit 203(i,j) supplied with the selection signal, the control signal, the display signal, and the sensing signal and capable of supplying a potential based on the sensing signal.

The pixel also includes a sensing element C capable of supplying the sensing signal, and a display element D supplied with a predetermined current.

The input/output circuit 203(i,j) includes a first transistor M1. A gate of the first transistor M1 is electrically connected to the first control line G1(i) capable of supplying the selection signal. A first electrode of the first transistor M1 is electrically connected to the signal line DL(j) capable of supplying the display signal.

The input/output circuit 203(i,j) includes a second transistor M2. A gate of the second transistor M2 is electrically connected to the second control line G2(i) capable of supplying the control signal. A first electrode of the second transistor M2 is electrically connected to the first wiring L1(j).

The input/output circuit 203(i,j) includes a driving transistor M0. A gate of the driving transistor M0 is electrically connected to a second electrode of the first transistor M1. A first electrode of the driving transistor M0 is electrically connected to the second wiring L2(j). A second electrode of the driving transistor M0 is electrically connected to a second electrode of the second transistor M2.

The conversion circuit 204(j) includes a transistor M6. A gate of the transistor M6 is electrically connected to a wiring BR capable of supplying a high power supply potential. A first electrode of the transistor M6 is electrically connected to a wiring VPO capable of supplying the high power supply potential. A second electrode of the transistor M6 is electrically connected to the second wiring L2(j). The conversion circuit 204(j) also includes a terminal OUT(j) electrically connected to the second wiring L2(j) and capable of supplying the sensing data.

A first electrode of the sensing element C is electrically connected to the second electrode of the first transistor M1. A second electrode of the sensing element C is electrically connected to the second electrode of the second transistor M2.

A first electrode of the display element D is electrically connected to the second electrode of the driving transistor M0. A second electrode of the display element D is electrically connected to the third wiring L3(j).

The input/output device 200 described in this embodiment includes the plurality of pixels 202(i,j) each including the input/output circuit 203(i,j) supplied with the selection signal, the control signal, the display signal including display data, and the sensing signal and capable of supplying the potential based on the sensing signal, the sensing element C capable of supplying the sensing signal, and the display element D supplied with the predetermined current, the base 210 provided with the plurality of pixels 202(i,j) arranged in a matrix, and the conversion circuit 204(j) electrically connected to one of the columns of the pixels 202(i,j) and capable of supplying the sensing data based on the sensing signal.

Accordingly, the sensing data which can be associated with data on the positions of the pixels arranged in a matrix can be supplied using a potential which changes in accordance with the sensing signal supplied by the sensing element included in each of the pixels. In addition, the display data can be displayed by the display element included in each of the pixels arranged in a matrix using the predetermined current based on the display signal. Thus, a novel input/output device which is highly convenient or reliable can be provided.

In the input/output device 200 described in this embodiment, the sensing element C and the display element D are provided in each of the pixels 202(i,j). Accordingly, coordinates where an image is displayed can be supplied using the sensing element C.

Note that the conversion circuit 204(j) can be provided apart from the input/output circuit, e.g., outside the region 201 so as not to be easily affected by noise.

The sensing element is not necessarily provided in each pixel, and one sensing element may be provided for a plurality of pixels. Accordingly, the number of control lines can be reduced.

Sensing data supplied from a plurality of pixels may be combined into one set of coordinates data.

The base 210 may have flexibility. The base 210 having flexibility may be used so that the input/output device 200 can be bent or folded.

Note that there is a case where part of the sensing element C is located close to another part in a folded state of the input/output device 200 which can be folded. Accordingly, part of the sensing element C may interfere with another part, resulting in false sensing. Specifically, in the case where a capacitor is used as the sensing element C, adjacent portions of an electrode interfere with each other.

A sensing element which is sufficiently small as compared with a folded size can be used in the input/output device 200. This can prevent interference of the sensing element C in a folded state.

A plurality of sensing elements C arranged in a matrix can be operated individually. Accordingly, the operation of a sensing element provided in a region where false sensing occurs can be stopped.

Note that sensing elements C and display elements D may be provided in some of the pixels arranged in a matrix. For example, the number of pixels provided with sensing elements C and display elements D may be smaller than the number of pixels provided with only display elements D. In such a case, display data can be displayed at a higher resolution than supplied sensing data.

The input/output device 200 may include a driver circuit GD which supplies the selection signal or the control signal.

The input/output device 200 may include a driver circuit SD which supplies the display signal.

The input/output device 200 may include the converter CONV which includes a plurality of conversion circuits 204(j) and supplies the sensing data.

The base 210 supporting the plurality of pixels 202(i,j) may support the driver circuit GD, the driver circuit SD, or the converter CONV.

Individual components included in the input/output device 200 will be described below. Note that in some cases, these components cannot be clearly distinguished and one component may serve also as another component or include part of another component.

For example, an input/output circuit electrically connected to a sensing element and a display element serves as a driver circuit for the sensing element and also as a driver circuit for the display element. A pixel including a sensing element and a display element serves as a display pixel and also as a sensing pixel.

The input/output device 200 differs from the input/output device 100 described with reference to FIGS. 1A and 1B in that the plurality of pixels 202(0, the plurality of first control lines G1(i), the plurality of second control lines G2(i), the plurality of signal lines DL(j), the plurality of first wirings L1(j), the plurality of second wirings L2(j), the plurality of third wirings L3(j), and the plurality of conversion circuits 204(j) are provided and that these components are supported by the base 210. Different components are described in detail below, and the above description is referred to for the other similar components.

### <<Entire Structure>>

The input/output device 200 includes the pixels 202(0, the first control lines G1(j), the second control lines G2(i), the signal lines DL(j), the first wirings L1(j), the second wirings L2(j), the third wirings L3(j), the conversion circuits 204(j), or the base 210.

In addition, the input/output device 200 may include the driver circuit GD which supplies the selection signal or the control signal, the driver circuit SD which supplies the display signal, or the converter CONV which supplies the sensing data.

### <<Pixel>>

The region 201 includes the plurality of pixels 202(i,j) arranged in a matrix of in rows and n column.

The input/output device 200 displays supplied display data in the region 201 and supplies sensing data obtained using the region 201.

The pixels 202(i,j) each include the sensing element C, and the sensing element C senses, for example, capacitance, illuminance, magnetic force, electric waves, pressure, or the like and supplies a voltage based on the sensed physical quantity to the first electrode and the second electrode. For example, a sensing element which supplies a sensing signal including a voltage that changes with a change in capacitance can be used as the sensing element C.

Note that the pixels 202(i,j) can supply the sensing signal supplied by the sensing element C and associated with coordinates of the pixels 202(i,j). Accordingly, a user of the input/output device 200 can input positional data using the region 201.

With the use of a proximity sensor, a contact sensor, or the like as the sensing element C, the input/output device 200 can be used as a touch panel.

Note that various gestures (e.g., tap, drag, swipe, and pinch in) can be made using a finger touching the input/output device 200 as a pointer. Data on the position, track, or the like of the finger touching the input/output device 200 are supplied to an arithmetic device. Then, if the arithmetic device determines that the data satisfy predetermined conditions, it can be recognized that a predetermined gesture has been given. Accordingly, an instruction associated with the predetermined gesture can be executed by the arithmetic device.

The pixels 202(i,j) each include the display element D, and the display element D is supplied with a current based on the display signal and displays the display data. For example, a display element which includes a first electrode, a second electrode overlapping with the first electrode, and a layer containing a light-emitting organic compound between the first electrode and the second electrode can be used as the display element D.

The pixels 202(i,j) include the input/output circuits 203(i,j). For example, input/output circuits similar to the input/output circuit 103 described in Embodiment 1 can be used as the input/output circuits 203(i,j).

### <<Control Line, Signal Line, Wiring>>

The region 201 includes the first control lines G1(i), the second control lines G2(i), the signal lines DL(j), the first wirings L1(j), the second wirings L2(j), or the third wirings L3(j). For example, lines similar to the first control line G1 described in Embodiment 1 or the like can be used as the first control lines G1(i).

### <<Base>>

The base 210 supports the pixels 202(i,j), the first control lines G1(j), the second control lines G2(i), the signal lines DL(j), the first wirings L1(j), the second wirings L2(j), or the third wirings L3(j),

The base 210 may support the conversion circuits 204(j).

For the base 210 having flexibility, an organic material, an inorganic material, a composite material of an organic material and an inorganic material, or the like can be used. For example, a base similar to a substrate T102 described in Embodiment 5 can be used as the base 210.

When a flexible material is used for the base 210, the input/output device 200 can be folded or unfolded.

The input/output device 200 in a folded state is highly portable. Accordingly, a user of the input/output device 200 can supply positional data by operating the input/output device 200 while holding it with one hand.

The input/output device 200 in an unfolded sate is highly browsable. Accordingly, a user of the input/output device 200 can supply positional data by operating the input/output device 200 while displaying a variety of data thereon.

### <<Conversion Circuit>>

A variety of circuits which can supply the terminals OUT(j) with a potential based on the high power supply potential and the sensing data based on the amount of current flowing through the first wirings L1(j) can be used as the conversion circuits 204(j). For example, conversion circuits similar to the conversion circuit 104 described in Embodiment 1 can be used as the conversion circuits 204(j).

### <<Converter CONV>>

The converter CONV includes the plurality of conversion circuits 204(j) and supplies the sensing data. For example, for the second wirings L2(j), respective conversion circuits 204(j) can be provided.

The converter CONV may be formed through the same process as the input/output circuits 203(i,j).

### <<Driver Circuit GD, Driver Circuit SD>>

The driver circuit GD or the driver circuit SD can be configured with a logic circuit using a variety of combinational circuits. For example, a shift register can be used.

A transistor can be used as a switch in the driver circuit GD or the driver circuit SD. For example, a transistor similar to transistors which can be used in the input/output circuit 103 described in Embodiment 1 can be used as the switch.

The driver circuit GD or the driver circuit SD may be formed through the same process as the input/output circuits 203(i,j).

### <Method 1 for Driving Input/Output Device>

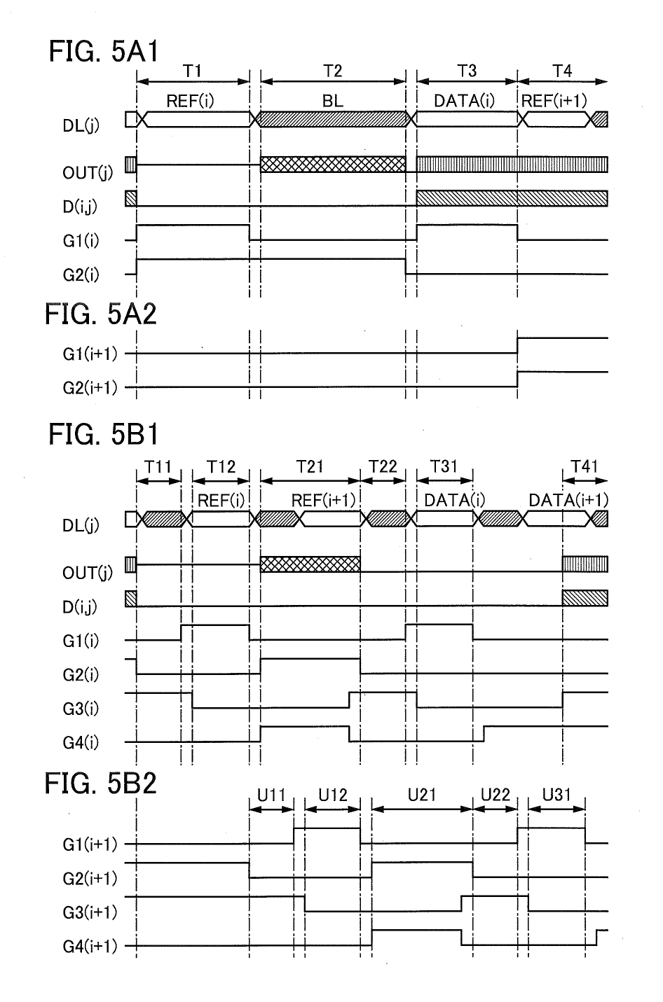

A method for driving the input/output device 200 in which the sensing data based on the voltage supplied by the sensing element C is supplied and display is performed in accordance with supplied display data will be described (see FIGS. 3A and 3B and FIGS. 5A1 and 5A2).

The method for driving the input/output device 100 can be employed as the method for driving the input/output device 200. Specifically, the input/output circuit 203(i,j) can be driven by the method including the first to fourth steps described in Embodiment 1.

Furthermore, the input/output circuit 203(i,j) and the input/output circuit 203(i+1,j) electrically connected to one of the signal lines DL(j) can be driven in combination with each other.

Specifically, the method for driving the input/output device 100 can be employed as the method for driving the input/output device 200 by replacing the terminal OUT with the terminal OUT(j), the display element D with the display element D(i,j), the first control line G1 with the first control line G1(i), and the second control line G2 with the second control line G2(i), except that a fourth step of the method for driving the pixel 202(i,j) differs from that of the method for driving the input/output device 100 described with reference to FIG. 1B in supplying a signal capable of turning on the first transistor M1 and the second transistor M2 in the pixel 202(i+1,j). Different components are described in detail below, and the above description is referred to for the other similar components.

### <<Fourth Step>>

In the fourth step, the selection signal capable of turning off the first transistor M1 in the pixel 202(i,j) is supplied to the first control line G1(i), and the control signal capable of turning off the second transistor M2 in the pixel 202(i,j) is supplied to the second control line G2(i).

In addition, the selection signal capable of turning off the first transistor M1 in the pixel 202(i+1,j) is supplied to the first control line G1(i+1), and the control signal capable of turning off the second transistor M2 in the pixel 202(i+1,j) is supplied to the second control line G2(i+1).

In addition, the potential based on the high power supply potential is supplied so that the driving transistor M0 in the pixel 202(i,j) supplies the predetermined current and the driving transistor M0 in the pixel 202(i+1,j) supplies the predetermined current based on the display signal supplied in the third step, and the conversion circuit 204(j) supplies the sensing data based on the sensing signal (see a period T4 in FIG. 5A1).

### <Structure Example 2 of Input/Output Device>

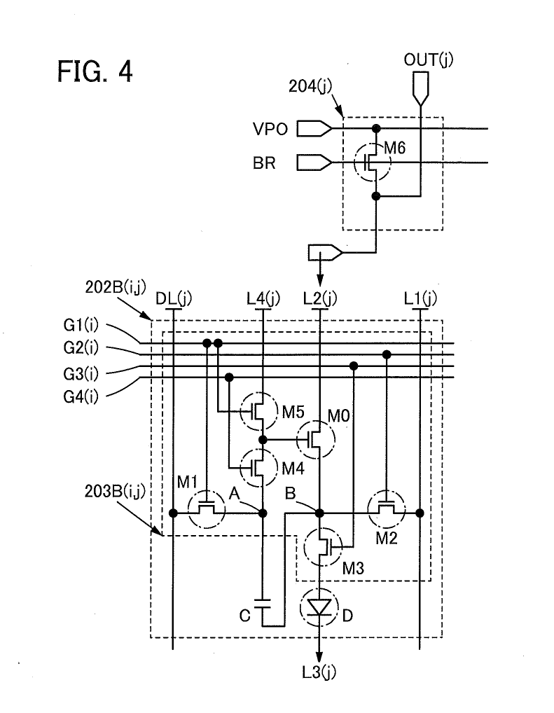

Another structure of an input/output device in one embodiment of the present invention will be described with reference to FIG. 4.

FIG. 4 is a circuit diagram of an input/output circuit 203B(i,j) whose structure is different from that of the input/output circuit 203(i,j) illustrated in FIG. 3B.

An input/output device 200B differs from the input/output device 200 described with reference to FIGS. 3A and 3B in that the input/output circuit 203B includes third to fifth transistors M3 to M5 and is electrically connected to third and fourth control lines G3(i) and G4(i). Different components are described in detail below, and the above description is referred to for the other similar components.

The input/output device 200B described in this embodiment includes a region 201. The region 201 includes a plurality of pixels 202B(i,j) arranged in a matrix of in rows and n columns Note that in and n are each a natural number greater than or equal to 1, and in or n is greater than or equal to 2. In addition, i is less than or equal to m, and j is less than or equal to n.

The input/output device 200B also includes a plurality of first control lines G1(i) which are electrically connected to rows of the plurality of pixels 202B(i,j) and which are capable of supplying a selection signal, a plurality of second control lines G2(i) which are electrically connected to the rows of the plurality of pixels 202B(i,j) and which are capable of supplying a first control signal, a plurality of third control lines G3(i) which are electrically connected to the rows of the plurality of pixels 202B(i,j) and which are capable of supplying a second control signal, and a plurality of fourth control lines G4(i) which are electrically connected to the rows of the plurality of pixels 202B(i,j) and which are capable of supplying a third control signal.

The input/output device 200B also includes a plurality of signal lines DL(j) which are electrically connected to columns of the plurality of pixels 202B(i,j) and which are capable of supplying a display signal including display data, a plurality of first wirings L1(j) which are electrically connected to the columns of the plurality of pixels 202B(i,j) and which are capable of supplying a first power supply potential, a plurality of second wirings L2(j) which are electrically connected to the columns of the plurality of pixels 202B(i,j) and which are capable of supplying a potential based on a high power supply potential, a plurality of third wirings L3(j) which are electrically connected to the columns of the plurality of pixels 202B(i,j) and which are capable of supplying a second power supply potential, and a plurality of fourth wirings L4(j) which are electrically connected to the columns of the plurality of pixels 202B(i,j) and which are capable of supplying a third power supply potential.

The input/output device 200B also includes a conversion circuit 204(j) which is electrically connected to one of the plurality of second wirings L2(j), which is supplied with the high power supply potential, and which is capable of supplying a potential based on the high power supply potential and supplying sensing data based on a sensing signal.

The input/output device 200B also includes a base 210 which supports the pixels 202B(i,j), the first to fourth control lines G1(i) to G4(i), the signal lines DL(i), and the first to fourth wirings L1(j) to L4(j).

Each of the pixels 202B(i,j) includes an input/output circuit 203B(i,j) supplied with the selection signal, the first to third control signals, the display signal, and the sensing signal and capable of supplying a potential based on the sensing signal.

The pixel also includes a sensing element C capable of supplying the sensing signal, and a display element D supplied with a predetermined current.

The input/output circuit 203B(i,j) includes a first transistor M1. A gate of the first transistor M1 is electrically connected to the first control line G1(i) capable of supplying the selection signal. A first electrode of the first transistor M1 is electrically connected to the signal line DL(j) capable of supplying the display signal.

The input/output circuit 203B(i,j) includes a second transistor M2. A gate of the second transistor M2 is electrically connected to the second control line G2(i) capable of supplying the first control signal. A first electrode of the second transistor M2 is electrically connected to the first wiring L1(j).

The input/output circuit 203B(i,j) includes a third transistor M3. A gate of the third transistor M3 is electrically connected to the third control line G3(i) capable of supplying the second control signal. A first electrode of the third transistor M3 is electrically connected to a second electrode of the second transistor M2.

The input/output circuit 203B(i,j) includes a fourth transistor M4. A gate of the fourth transistor M4 is electrically connected to the fourth control line G4(i) capable of supplying the third control signal. A first electrode of the fourth transistor M4 is electrically connected to a second electrode of the first transistor M1.

The input/output circuit 203B(i,j) includes a fifth transistor M5. A gate of the fifth transistor M5 is electrically connected to the first control line G1(i) capable of supplying the selection signal. A first electrode of the fifth transistor M5 is electrically connected to a second electrode of the fourth transistor M4. A second electrode of the fifth transistor M5 is electrically connected to the fourth wiring L4(j).

The input/output circuit 203B(i,j) includes a driving transistor M0. A gate of the driving transistor M0 is electrically connected to the second electrode of the fourth transistor M4. A first electrode of the driving transistor M0 is electrically connected to the second wiring L2(j). A second electrode of the driving transistor M0 is electrically connected to the second electrode of the second transistor M2.

The conversion circuit 204(j) includes a transistor M6. A gate of the transistor M6 is electrically connected to a wiring BR capable of supplying a high power supply potential. A first electrode of the transistor M6 is electrically connected to a wiring VPO capable of supplying the high power supply potential. A second electrode of the transistor M6 is electrically connected to the second wiring L2(j). The conversion circuit 204(j) also includes a terminal OUT(j) electrically connected to the second wiring L2(j) and capable of supplying the sensing data.

A first electrode of the sensing element C is electrically connected to the second electrode of the first transistor M1. A second electrode of the sensing element C is electrically connected to the second electrode of the second transistor M2.

A first electrode of the display element D is electrically connected to a second electrode of the third transistor M3. A second electrode of the display element D is electrically connected to the third wiring L3(j).

The input/output device 200B described in this embodiment includes the plurality of pixels 202B(i,j) each including the input/output circuit 203B(i,j) supplied with the selection signal, the control signals, the display signal including display data, and the sensing signal and capable of supplying the potential based on the sensing signal, the sensing element C capable of supplying the sensing signal, and the display element D supplied with the predetermined potential, the base 210 provided with the plurality of pixels 202B(i,j) arranged in a matrix, and the conversion circuit 204(j) electrically connected to one of the columns of the pixels 202B(i,j) and capable of supplying the sensing data based on the sensing signal.

Accordingly, the sensing data which can be associated with data on the position of the pixels arranged in a matrix can be supplied using a potential which changes in accordance with the sensing signal supplied by the sensing element included in each of the pixels. In addition, the display data can be displayed by the display element included in each of the pixels arranged in a matrix using the predetermined current based on the display signal. Thus, a novel input/output device which is highly convenient or reliable can be provided.

### <Method 2 for Driving Input/Output Device>

A method for driving the input/output device 200B which is supplied with the sensing data based on the voltage supplied by the sensing element C and which performs display in accordance with supplied display data will be described (see FIG. 4 and FIGS. 5B 1 and 5B2).

The method for driving the input/output device 100B can be employed as the method for driving the input/output device 200B. Specifically, the input/output circuit 203B(i,j) can be driven by the method including the first to sixth steps described in Embodiment 2.

Furthermore, the input/output circuit 203B(i,j) and the input/output circuit 203B(i+1,j) electrically connected to one of the signal lines DL(j) can be driven in combination with each other.

Specifically, in a period T21 for driving the input/output circuit 203B(i,j) by the third step, the input/output circuit 203B(i+1,j) can be driven by the first step (see Ulf in FIG. 5B2) and the second step (see U12 in FIG. 5B2).

In a period T22 and a period T31 for driving the input/output circuit 203B(i,j) by the fourth and fifth steps, the input/output circuit 203B(i+1 j) can be driven by the third step (see U21 in FIG. 5B2).

After the input/output circuit 203B(i,j) is driven by the fifth step, the input/output circuit 203B(i+1,j) can be driven by the fourth step (see U22 in FIG. 5B2) and the fifth step (see U31 in FIG. 5B2).

Note that this embodiment can be combined with any of the other embodiments in this specification as appropriate.

### Embodiment 4

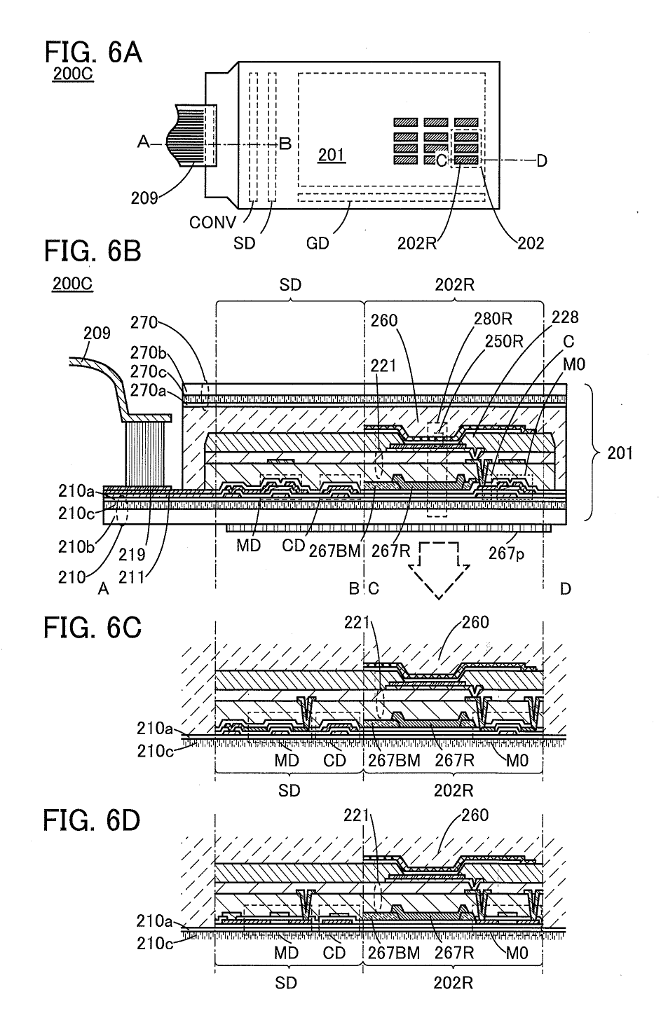

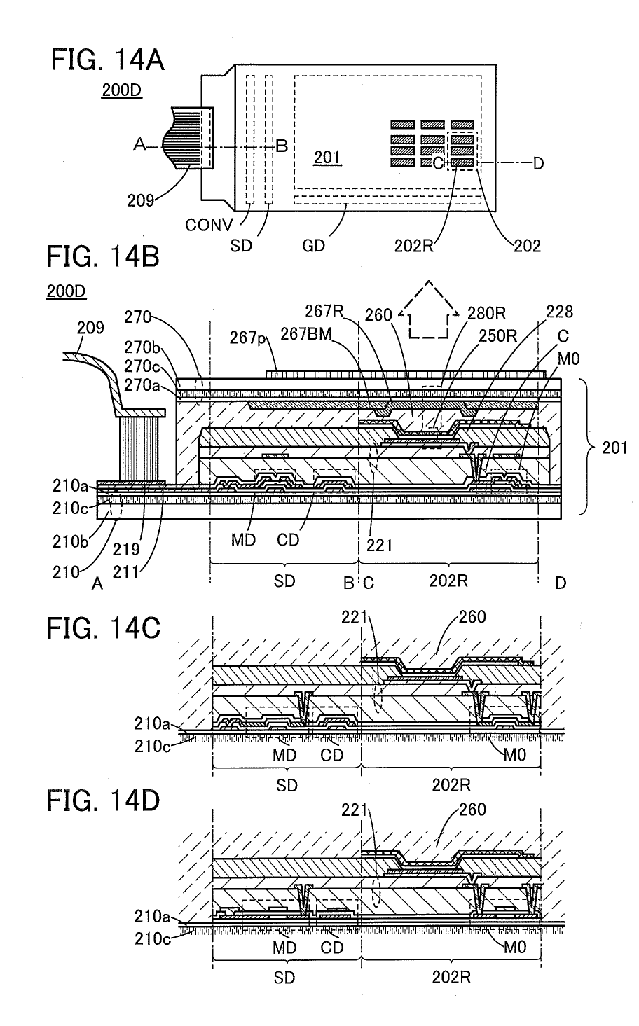

In this embodiment, structures of input/output devices of one embodiment of the present invention will be described with reference to FIGS. 6A to 6D and FIGS. 14A to 14D.

FIGS. 6A to 6D illustrate a structure of an input/output device in one embodiment of the present invention. FIG. 6A is a top view of an input/output device 200C in one embodiment of the present invention, and FIG. 6B is a cross-sectional view including cross sections taken along cutting-plane lines A-B and C-D in FIG. 6A.

### <Structure Example 1 of Input/Output Device>

The input/output device 200C described in this embodiment includes a base 210, a base 270 overlapping with the base 210, a sealant 260 between the base 210 and the base 270, a pixel 202, a driver circuit GD for supplying a control signal to the pixel 202, a driver circuit SD for supplying a display signal to the pixel 202, a converter CONV supplied with sensing data, and a region 201 provided with the pixel 202 (see FIGS. 6A and 6B).

The base 210 includes a barrier film 210a, a flexible base 210b, and a resin layer 210c for attaching the barrier film 210a and the flexible base 210b.

The base 270 includes a barrier film 270a, a flexible base 270b, and a resin layer 270c for attaching the barrier film 270a and the flexible base 270b.

The sealant 260 attaches the base 210 and the base 270.

The pixel 202 includes a sub-pixel 202R, is supplied with a display signal, and supplies sensing data (see FIG. 6A). Note that the pixel 202 includes the sub-pixel 202R for displaying red, a sub-pixel for displaying green, and a sub-pixel for displaying blue.

The sub-pixel 202R includes an input/output circuit including a driving transistor M0, a sensing element C, and a display module 280R provided with a display element (see FIG. 6B).

The display module 280R includes a light-emitting element 250R and a coloring layer 267R overlapping with the light-emitting element 250R on a light-emitting side. Note that the light-emitting element 250R is one embodiment of the display element.

The light-emitting element 250R includes a lower electrode, an upper electrode, and a layer containing a light-emitting organic compound.

The input/output circuit includes the driving transistor M0 and is provided between the base 210 and the light-emitting element 250R with an insulating layer 221 provided therebetween.

A second electrode of the driving transistor M0 is electrically connected to the lower electrode of the light-emitting element 250R through an opening provided in the insulating layer 221.

A first electrode of the sensing element C is electrically connected to a gate of the driving transistor M0. A second electrode of the sensing element C is electrically connected to the second electrode of the driving transistor M0.

The driver circuit SD includes a transistor MD and a capacitor CD.

A wiring 211 is electrically connected to a terminal 219. The terminal 219 is electrically connected to a flexible printed board 209.

Note that a light-blocking layer 267BM is provided so as to surround the coloring layer 267R.

In addition, a partition 228 is formed so as to cover an end portion of the lower electrode of the light-emitting element 250R.

A protective film 267p may be provided in a position overlapping with the region 201 (see FIG. 6B).

Accordingly, the input/output device 200C can display display data on the side where the base 210 is provided. In addition, the input/output device 200C can supply sensing data by sensing an object that is located close to or in contact with the side where the base 210 is provided.

### <<Entire Structure>>

The input/output device 200C includes the base 210, the base 270, the sealant 260, the pixel 202, the driver circuit GD, the driver circuit SD, the converter CONV, or the region 201.

### <<Base>>

There is no particular limitation on the base 210 as long as the base 210 has heat resistance high enough to withstand a manufacturing process and a thickness and a size which can be used in a manufacturing apparatus. Note that a base similar to the base 210 can be used as the base 270.

For the base 210, an organic material, an inorganic material, a composite material of an organic material and an inorganic material, or the like can be used.

For example, an inorganic material such as glass, ceramic, or metal can be used for the base 210.

Specifically, alkali-free glass, soda-lime glass, potash glass, crystal glass, or the like can be used for the base 210.

Specifically, a metal oxide film, a metal nitride film, a metal oxynitride film, or the like can be used for the base 210. For example, a silicon oxide film, a silicon nitride film; a silicon oxynitride film, an alumina film, or the like can be used for the base 210.

Specifically, SUS, aluminum, or the like can be used for the base 210.

For example, an organic material such as a resin, a resin film, or plastic can be used for the base 210.

Specifically, a resin film or a resin plate of polyester, polyolefin, polyamide, polyimide, polycarbonate, an acrylic resin, or the like can be used as the base 210.

For example, a composite material such as a resin film to which a metal plate, a thin glass plate, or a film of an inorganic material is attached can be used for the base 210.

For example, a composite material formed by dispersing a fibrous or particulate metal, glass, inorganic material, or the like into a resin film can be used for the base 210.

For example, a composite material formed by dispersing a fibrous or particulate resin, organic material, or the like into an inorganic material can be used for the base 210.

For the base 210, a single-layer material or a stacked-layer material in which a plurality of layers are stacked can be used. For example, a stacked-layer material in which a base, an insulating layer that prevents diffusion of impurities contained in the base, and the like are stacked can be used for the base 210.

Specifically, a stacked-layer material in which glass and one or a plurality of films that prevents diffusion of impurities contained in the glass and that are selected from a silicon oxide film, a silicon nitride film, a silicon oxynitride film, and the like are stacked can be used for the base 210.

Alternatively, a stacked-layer material in which a resin and a film that prevents diffusion of impurities permeating the resin, such as a silicon oxide film, a silicon nitride film, or a silicon oxynitride film are stacked can be used for the base 210.

Specifically, a stack body including the flexible base 210b, the barrier film 210a that prevents diffusion of impurities into the light-emitting element 250R, and the resin layer 210c that attaches the barrier film 210a and the base 210b can be used.

Specifically, a stack body including the flexible base 270b, the barrier film 270a that prevents diffusion of impurities into the light-emitting element 2508, and the resin layer 270c that attaches the barrier film 270a and the base 270b can be used.

### <<Sealant>>

There is no particular limitation on the sealant 260 as long as the sealant 260 attaches the base 210 and the base 270 to each other.

For the sealant 260, an inorganic material, an organic material, a composite material of an inorganic material and an organic material, or the like can be used.

For example, a glass layer with a melting point of 400° C. or lower, preferably 300° C. or lower, an adhesive, or the like can be used.

For the sealant 260, an organic material such as a photo-curable adhesive, a reactive curable adhesive, a thermosetting adhesive, and/or an anaerobic adhesive can be used.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, or the like can be used.

### <<Pixel>>

A variety of transistors can be used as the driving transistor M0.

For example, a transistor in which a Group 4 element, a compound semiconductor, an oxide semiconductor, or the like is used for the semiconductor layer can be used. Specifically, a semiconductor containing silicon, a semiconductor containing gallium arsenide, an oxide semiconductor containing indium, or the like can be used for the semiconductor layer of the driving transistor M0.

For example, single crystal silicon, polysilicon, amorphous silicon, or the like can be used for the semiconductor layer of the driving transistor M0.

For example, a bottom-gate transistor, a top-gate transistor, or the like can be used.

An element which can sense capacitance, illuminance, magnetic force, electric waves, pressure, or the like and supply a voltage based on the sensed physical quantity to a first electrode and a second electrode can be used as the sensing element C.

Specifically, a capacitor which senses a change in capacitance can be used as the sensing element C.

A variety of display elements can be used in the display module 280R. For example, an organic EL element which includes a lower electrode, an upper electrode, and a layer containing a light-emitting organic compound between the lower electrode and the upper electrode can be used as the display element.

Note that in the case where a light-emitting element is used as the display element, a light-emitting element combined with a microcavity structure can be used. For example, the microcavity structure may be formed using the lower electrode and the upper electrode of the light-emitting element so that light with a specific wavelength can be extracted from the light-emitting element efficiently.

Specifically, a reflective film which reflects visible light is used as one of the upper and lower electrodes, and a semi-transmissive and semi-reflective film which transmits part of visible light and reflects part of visible light is used as the other. The upper electrode is located with respect to the lower electrode so that light with a specific wavelength can be extracted efficiently.

As the coloring layer 267R, a layer containing a material such as a pigment or a dye can be used. Accordingly, the display module 280R can emit light of a particular color.

For example, a layer which emits light including red, green, and blue light can be used as the layer containing a light-emitting organic compound. Furthermore, the layer may be used in the display module 280R together with a microcavity for extracting red light efficiently and a coloring layer which transmits red light, in a display module 280G together with a microcavity for extracting green light efficiently and a coloring layer which transmits green light, or in a display module 280B together with a microcavity for extracting blue light efficiently and a coloring layer which transmits blue light.

Note that a layer which emits light including yellow light can also be used as the layer containing a light-emitting organic compound. Furthermore, the layer may be used in a display module 280Y together with a microcavity for extracting yellow light efficiently and a coloring layer which transmits yellow light.

### ((Driver Circuit))

A variety of transistors can be used as the transistor MD of the driver circuit SD. For example, a transistor similar to the driving transistor M0 can be used as the transistor MD.

In the case where a capacitor is used as the sensing element C, an element similar to the sensing element C can be used as the capacitor CD.

### <<Converter>>

The converter CONV includes a plurality of conversion circuits. A variety of transistors can be used in the conversion circuits. For example, a transistor similar to the driving transistor M0 can be used.

### <<Region>>

The region 201 includes a plurality of pixels 202 arranged in a matrix. The region 201 can display the display data and can supply the sensing data associated with coordinates data of the pixels provided in the region 201. For example, the region 201 can sense the presence or absence of an object located close to the region 201 and can supply the result together with coordinates data.

### <<Others>>

A conductive material can be used for the wiring 211 or the terminal 219.

For example, an inorganic conductive material, an organic conductive material, metal, conductive ceramic, or the like can be used for the wiring.

Specifically, a metal element selected from aluminum, gold, platinum, silver, chromium, tantalum, titanium, molybdenum, tungsten, nickel, iron, cobalt, palladium, and manganese; an alloy including any of the above-described metal elements; an alloy including any of the above-described metal elements in combination; or the like can be used for the wiring or the like.

Alternatively, a conductive oxide such as indium oxide, indium tin oxide, indium zinc oxide, zinc oxide, or zinc oxide to which gallium is added can be used.

Alternatively, graphene or graphite can be used. A film containing graphene can be formed, for example, by reducing a film containing graphene oxide. As a reducing method, a method with application of heat, a method using a reducing agent, or the like can be given.

Alternatively, a conductive high molecule can be used.

For the light-blocking layer 267BM, a light-blocking material can be used. For example, a resin in which a pigment is dispersed, a resin containing a dye, or an inorganic film such as a black chromium film can be used for the light-blocking layer 267BM. For the light-blocking layer 267BM, carbon black, a metal oxide, a composite oxide containing a solid solution of a plurality of metal oxides, or the like can be used.

An insulating material can be used for the partition 228. For example, an inorganic material, an organic material, a stacked-layer material of an inorganic material and an organic material, or the like can be used. Specifically, a film containing silicon oxide, silicon nitride, or the like, acrylic, polyimide, a photosensitive resin, or the like can be used.

The protective film 267p can be provided on the display surface side of the input/output device. For example, an inorganic material, an organic material, a composite material of an inorganic material and an organic material, or the like can be used for the protective film 267p. Specifically, a ceramic coat layer containing alumina, silicon oxide, or the like, a hard coat layer containing a UV curable resin or the like, an anti-reflection film, a circularly polarizing plate, or the like can be used.

### <Modification Example 1 of Display Portion>

A variety of transistors can be used in the input/output device 200C.

Structures in which bottom-gate transistors are used in the input/output device 200C are illustrated in FIGS. 6B and 6C.

For example, a semiconductor layer containing an oxide semiconductor, amorphous silicon, or the like can be used in the driving transistor M0 and the transistor MD shown in FIG. 6B.

For example, a film represented by an In-M-Zn oxide that contains at least indium (In), zinc (Zn), and M (a metal such as Al, Ga, Ge, Y, Zr, Sn, La, Ce, or Hf) is preferably included. Alternatively, both In and Zn are preferably contained.

As a stabilizer, gallium (Ga), tin (Sn), hafnium (Hf), aluminum (Al), zirconium (Zr), or the like can be given. As another stabilizer, lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) can be given.

As an oxide semiconductor included in an oxide semiconductor film, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, an In—Hf—Al—Zn-based oxide, and an In—Ga-based oxide.

Note that here, an “In—Ga—Zn-based oxide” means an oxide containing In, Ga, and Zn as its main components and there is no limitation on the ratio of In:Ga:Zn. The In—Ga—Zn-based oxide may contain another metal element in addition to In, Ga, and Zn.

For example, a semiconductor layer containing polycrystalline silicon that is obtained by crystallization process such as laser annealing can be used in the driving transistor M0 and the transistor MD shown in FIG. 6C.

A structure in which top-gate transistors are used in the input/output device 200C is shown in FIG. 6D.

For example, a semiconductor layer containing polycrystalline silicon, a single crystal silicon film that is transferred from a single crystal silicon substrate, or the like can be used in the driving transistor M0 and the transistor MD shown in FIG. 6D.

### <Structure Example 2 of Input/Output Device>

FIGS. 14A to 14D illustrate a structure of an input/output device in one embodiment of the present invention. FIG. 14A is a top view of an input/output device 200D in one embodiment of the present invention, and FIG. 14B is a cross-sectional view including cross sections taken along cutting-plane lines A-B and C-D in FIG. 14A.

The input/output device 200D described in this embodiment differs from the input/output device 200C described with reference to FIGS. 6A to 6D in that the coloring layer 267R and the light-blocking layer 267BM surrounding the coloring layer 267R are provided between the base 270 and the light-emitting element 250R, that the protective film 26′7p is provided on the base 270 side, and that the display module 280R emits light to the side where the base 270 is provided. As the other components, similar components can be used

Accordingly, the input/output device 200D can display display data on the side where the base 270 is provided. In addition, the input/output device 200D can supply sensing data by sensing an object that is located close to or in contact with the side where the base 270 is provided.

Note that this embodiment can be combined with any of the other embodiments in this specification as appropriate.

### Embodiment 5

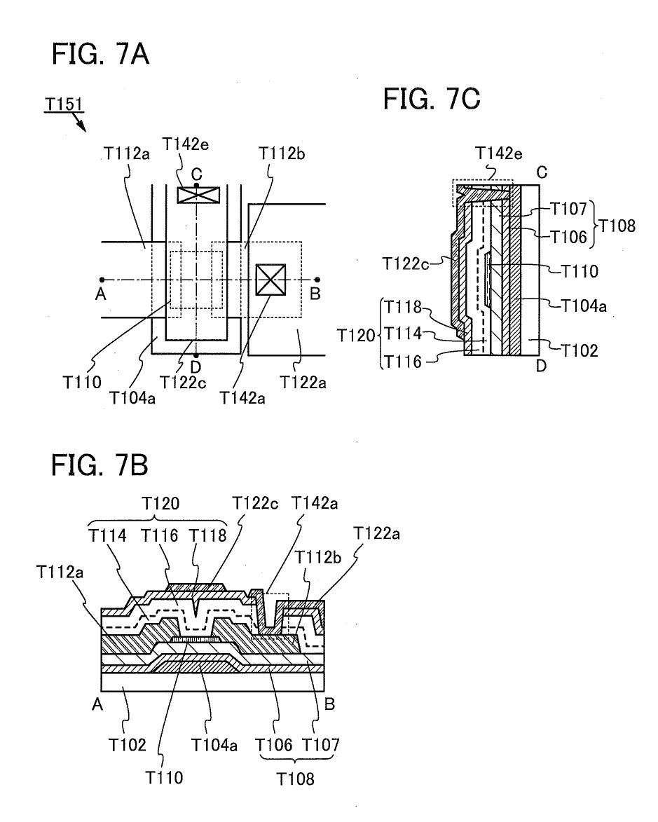

In this embodiment, a structure of a transistor that can be used in a conversion circuit in one embodiment of the present invention or the like will be described with reference to FIGS. 7A to 7C.

FIGS. 7A to 7C are a top view and cross-sectional views of a transistor T151. FIG. 7A is a top view of the transistor T151. FIG. 7B corresponds to a cross-sectional view of a cross section taken along dashed-dotted line A-B in FIG. 7A. FIG. 7C is a cross-sectional view of a cross section taken along dashed-dotted line C-D in FIG. 7A. Note that in FIG. 7A, some components are not illustrated for clarity.

Note that in this embodiment, a first electrode refers to one of a source electrode and a drain electrode of a transistor, and a second electrode refers to the other.

The transistor T151 includes a gate electrode T104a provided over a substrate T102, a first insulating film T108 that includes insulating films T106 and T107 and is formed over the substrate T102 and the gate electrode T104a, an oxide semiconductor film T110 overlapping with the gate electrode T104a with the first insulating film T108 provided therebetween, and a first electrode T112a and a second electrode T112b in contact with the oxide semiconductor film T110.

In addition, over the first insulating film T108, the oxide semiconductor film T110, the first electrode T112a, and the second electrode T112b, a second insulating film T120 including insulating films T114, T116, and T118 and a gate electrode T122c formed over the second insulating film T120 are provided.

The gate electrode T122c is connected to the gate electrode T104a through an opening T142e provided in the first insulating film T108 and the second insulating film T120. In addition, a conductive film T122a serving as a pixel electrode is formed over the insulating film T118. The conductive film T122a is connected to the second electrode T112b through an opening T142a provided in the second insulating film T120.

Note that the first insulating film T108 serves as a first gate insulating film of the transistor T151, and the second insulating film T120 serves as a second gate insulating film of the transistor T151. Furthermore, the conductive film T122a serves as a pixel electrode.

In the transistor T151 of one embodiment of the present invention, in the channel width direction, the oxide semiconductor film T110 between the first insulating film T108 and the second insulating film T120 is provided between the gate electrode T104a and the gate electrode T122c. In addition, as illustrated in FIG. 7A, the gate electrode T104a overlaps with side surfaces of the oxide semiconductor film T110 with the first insulating film T108 provided therebetween, when seen from the above.

A plurality of openings are provided in the first insulating film T108 and the second insulating film T120. Typically, as illustrated in FIG. 7B, the opening T142a through which part of the second electrode T112b is exposed is provided. Furthermore, the opening T142e is provided as illustrated in FIG. 7C.

Through the opening T142a, the second electrode T112b is connected to the conductive film T122a.

In addition, through the opening T142e, the gate electrode T104a is connected to the gate electrode T122c.

When the gate electrode T104a and the gate electrode T122c are included and the same potential is applied to the gate electrode T104a and the gate electrode T122c, carriers flow in a wide region in the oxide semiconductor film T110. Accordingly, the amount of carriers that move in the transistor T151 increases.

As a result, the on-state current of the transistor T151 is increased, and the field-effect mobility is increased to greater than or equal to 10 cm²/V·s or to greater than or equal to 20 cm²/V·s, for example. Note that here, the field-effect mobility is not an approximate value of the mobility as the physical property of the oxide semiconductor film but is the apparent field-effect mobility in a saturation region of the transistor, which is an indicator of current drive capability.

An increase in field-effect mobility becomes significant when the channel length (also referred to as L length) of the transistor is longer than or equal to 0.5 μm and shorter than or equal to 6.5 μm, preferably longer than 1 μm and shorter than 6 μm, further preferably longer than 1 μm and shorter than or equal to 4 μm, still further preferably longer than 1 μm and shorter than or equal to 3.5 μm, yet still further preferably longer than 1 μm and shorter than or equal to 2.5 μm. Furthermore, with a short channel length longer than or equal to 0.5 μm and shorter than or equal to 6.5 μm, the channel width can also be short.

The transistor includes the gate electrode T104a and the gate electrode T122c, each of which has a function of blocking an external electric field; thus, charges such as a charged particle between the substrate T102 and the gate electrode T104a and over the gate electrode T122c do not affect the oxide semiconductor film T110. Thus, degradation due to a stress test (e.g., a negative gate bias temperature (−GBT) stress test in which a negative potential is applied to a gate electrode) can be reduced, and changes in the rising voltages of on-state current at different drain voltages can be suppressed.

The BT stress test is one kind of accelerated test and can evaluate, in a short time, change in characteristics (i.e., a change over time) of transistors, which is caused by long-term use. In particular, the amount of change in threshold voltage of a transistor in the BT stress test is an important indicator when examining the reliability of the transistor. If the amount of change in the threshold voltage in the BT stress test is small, the transistor has higher reliability.

The substrate T102 and individual components included in the transistor T151 will be described below.

### <<Substrate T102>>

For the substrate T102, a glass material such as aluminosilicate glass, aluminoborosilicate glass, or barium borosilicate glass is used. In the mass production, for the substrate T102, a mother glass with any of the following sizes is preferably used: the 8th generation (2160 mm×2460 mm), the 9th generation (2400 mm×2800 mm, or 2450 mm×3050 mm), the 10th generation (2950 mm×3400 mm), and the like. A high process temperature and a long period of process time drastically shrink the mother glass. Thus, in the case where mass production is performed with the use of the mother glass, the heating treatment in the manufacturing process is preferably performed at 600° C. or lower, further preferably 450° C. or lower, still further preferably 350° C. or lower.

### <<Gate Electrode T104a>>

The gate electrode T104a can be formed using a metal element selected from aluminum, chromium, copper, tantalum, titanium, molybdenum, and tungsten, an alloy containing any of these metal elements as a component, an alloy containing these metal elements in combination, or the like. In addition, the gate electrode T104a may have a single-layer structure or a stacked-layer structure including two or more layers. For example, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like can be given. Alternatively, an alloy film or a nitride film in which aluminum and one or more elements selected from titanium, tantalum, tungsten, molybdenum, chromium, neodymium, and scandium are contained may be used. The gate electrode T104a can be formed by a sputtering method, for example.

### <<First Insulating Film T108>>

An example in which the first insulating film T108 has a two-layer structure of the insulating film T106 and the insulating film T107 is illustrated. Note that the structure of the first insulating film T108 is not limited thereto, and for example, the first insulating film T108 may have a single-layer structure or a stacked-layer structure including three or more layers.

The insulating film T106 is formed to have a single-layer structure or a stacked-layer structure using, for example, any of a silicon nitride oxide film, a silicon nitride film, an aluminum oxide film, and the like with a PE-CVD apparatus. In the case where the insulating film T106 has a stacked-layer structure, it is preferable that a silicon nitride film with fewer defects be provided as a first silicon nitride film, and a silicon nitride film from which hydrogen and ammonia are less likely to be released be provided as a second silicon nitride film over the first silicon nitride film. As a result, hydrogen and nitrogen contained in the insulating film T106 can be prevented from moving or diffusing into the oxide semiconductor film T110 formed later.

The insulating film T107 is formed to have a single-layer structure or a stacked-layer structure using any of a silicon oxide film, a silicon oxynitride film, and the like with a PE-CVD apparatus.

The first insulating film T108 can have a stacked-layer structure, for example, in which a 400-nm-thick silicon nitride film used as the insulating film T106 and a 50-nm-thick silicon oxynitride film used as the insulating film T107 are formed in this order. The silicon nitride film and the silicon oxynitride film are preferably formed in succession in a vacuum, in which case entry of impurities is suppressed. Note that the first insulating film T108 in a position overlapping with the gate electrode T104a serves as a gate insulating film of the transistor T151. Silicon nitride oxide refers to an insulating material that contains more nitrogen than oxygen, whereas silicon oxynitride refers to an insulating material that contains more oxygen than nitrogen.

### <<Oxide Semiconductor Film T110>>

For the oxide semiconductor film T110, an oxide semiconductor is preferably used. As the oxide semiconductor, a film represented by an In-M-Zn oxide that contains at least indium (In), zinc (Zn), and M (a metal such as Al, Ga, Ge, Y, Zr, Sn, La, Ce, or Hf) is preferably included. Alternatively, both In and Zn are preferably contained. In order to reduce fluctuations in electrical characteristics of the transistor including the oxide semiconductor, the oxide semiconductor preferably contains a stabilizer in addition to In and Zn.

As a stabilizer, gallium (Ga), tin (Sn), hafnium (Hf), aluminum (Al), zirconium (Zr), or the like can be given. As another stabilizer, lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), or lutetium (Lu) can be given.

As an oxide semiconductor included in the oxide semiconductor film T110, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, an “In—Ga—Zn-based oxide” means an oxide containing In, Ga, and Zn as its main components and there is no limitation on the ratio of In:Ga:Zn. The In—Ga—Zn-based oxide may contain another metal element in addition to In, Ga, and Zn.

The oxide semiconductor film T110 can be formed by a sputtering method, a molecular beam epitaxy (MBE) method, a CVD method, a pulse laser deposition method, an atomic layer deposition (ALD) method, or the like as appropriate. In particular, the oxide semiconductor film T110 is preferably formed by the sputtering method because the oxide semiconductor film T110 can be dense.

In the formation of an oxide semiconductor film as the oxide semiconductor film T110, the hydrogen concentration in the oxide semiconductor film is preferably reduced as much as possible. To reduce the hydrogen concentration, for example, in the case of a sputtering method, a deposition chamber needs to be evacuated to a high vacuum and also a sputtering gas needs to be highly purified. As an oxygen gas or an argon gas used for a sputtering gas, a gas which is highly purified to have a dew point of −40° C. or lower, preferably −80° C. or lower, further preferably −100° C. or lower, or still further preferably −120° C. or lower is used, whereby entry of moisture or the like into the oxide semiconductor film can be minimized

In order to remove moisture remaining in the deposition chamber, an entrapment vacuum pump such as a cryopump, an ion pump, or a titanium sublimation pump is preferably used. A turbo molecular pump provided with a cold trap may be alternatively used. When the deposition chamber is evacuated with a cryopump, which has a high capability in removing a compound including a hydrogen atom such as water (H₂O), a compound including a carbon atom, and the like, the concentration of an impurity to be contained in an oxide semiconductor film formed in the deposition chamber can be reduced.

When the oxide semiconductor film as the oxide semiconductor film T110 is formed by a sputtering method, the relative density (filling factor) of a metal oxide target that is used for the film formation is greater than or equal to 90% and less than or equal to 100%, preferably greater than or equal to 95% and less than or equal to 100%. With the use of the metal oxide target having high relative density, a dense oxide semiconductor film can be formed.

Note that to reduce the impurity concentration of the oxide semiconductor film, it is also effective to form the oxide semiconductor film as the oxide semiconductor film T110 while the substrate T102 is kept at high temperature. The temperature at which the substrate T102 is heated may be higher than or equal to 150° C. and lower than or equal to 450° C.; the substrate temperature is preferably higher than or equal to 200° C. and lower than or equal to 350° C.

Next, first heat treatment is preferably performed. The first heat treatment may be performed at a temperature higher than or equal to 250° C. and lower than or equal to 650° C., preferably higher than or equal to 300° C. and lower than or equal to 500° C., in an inert gas atmosphere, an atmosphere containing an oxidizing gas at 10 ppm or more, or a reduced pressure state. Alternatively, the first heat treatment may be performed in such a manner that heat treatment is performed in an inert gas atmosphere, and then another heat treatment is performed in an atmosphere containing an oxidizing gas at 10 ppm or more, in order to compensate for desorbed oxygen. By the first heat treatment, the crystallinity of the oxide semiconductor that is used for the oxide semiconductor film T110 can be improved, and in addition, impurities such as hydrogen and water can be removed from the first insulating film T108 and the oxide semiconductor film T110. The first heat treatment may be performed before processing into the oxide semiconductor film T110 having an island shape.

### <<First Electrode, Second Electrode>>

The first electrode T112a and the second electrode T112b can be formed using a conductive film T112 having a single-layer structure or a stacked-layer structure with any of aluminum, titanium, chromium, nickel, copper, yttrium, zirconium, molybdenum, silver, tantalum, and tungsten, or an alloy containing any of these metals as its main component. In particular, one or more elements selected from aluminum, chromium, copper, tantalum, titanium, molybdenum, and tungsten are preferably included. For example, a two-layer structure in which a titanium film is stacked over an aluminum film, a two-layer structure in which a titanium film is stacked over a tungsten film, a two-layer structure in which a copper film is formed over a copper-magnesium-aluminum alloy film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used. The conductive film can be formed by a sputtering method, for example.

### <<Insulating Films T114, T116>>

An example in which the second insulating film T120 has a three-layer structure of the insulating films T114, T116, and T118 is illustrated. Note that the structure of the second insulating film T120 is not limited thereto, and for example, the second insulating film T120 may have a single-layer structure, a stacked-layer structure including two layers, or a stacked-layer structure including four or more layers.

For the insulating films T114 and T116, an inorganic insulating material containing oxygen can be used in order to improve the characteristics of the interface with the oxide semiconductor used for the oxide semiconductor film T110. As examples of the inorganic insulating material containing oxygen, a silicon oxide film, a silicon oxynitride film, and the like can be given. The insulating films T114 and T116 can be formed by a PE-CVD method, for example.

The thickness of the insulating film T114 can be greater than or equal to 5 nm and less than or equal to 150 nm, preferably greater than or equal to 5 nm and less than or equal to 50 nm, more preferably greater than or equal to 10 nm and less than or equal to 30 nm. The thickness of the insulating film T116 can be greater than or equal to 30 nm and less than or equal to 500 nm, preferably greater than or equal to 150 nm and less than or equal to 400 nm.

Furthermore, the insulating films T114 and T116 can be formed using insulating films formed of the same kinds of materials; thus, a boundary between the insulating film T114 and the insulating film T116 cannot be clearly observed in some cases. Thus, in this embodiment, the boundary between the insulating film T114 and the insulating film T116 is shown by a dashed line. Although a two-layer structure of the insulating films T114 and T116 is described in this embodiment, the present invention is not limited to this. For example, a single-layer structure of the insulating film T114, a single-layer structure of the insulating film T116, or a stacked-layer structure including three or more layers may be used.

The insulating film T118 is a film formed using a material that can prevent an external impurity, such as water, alkali metal, or alkaline earth metal, from diffusing into the oxide semiconductor film T110, and that further contains hydrogen.

For example, a silicon nitride film, a silicon nitride oxide film, or the like having a thickness of greater than or equal to 150 nm and less than or equal to 400 nm can be used as the insulating film T118. In this embodiment, a 150-nm-thick silicon nitride film is used as the insulating film T118.

The silicon nitride film is preferably formed at a high temperature to have an improved blocking property against impurities or the like; for example, the silicon nitride film is preferably formed at a temperature in the range from the substrate temperature of 100° C. to the strain point of the substrate, more preferably at a temperature in the range from 300° C. to 400° C. When the silicon nitride film is formed at a high temperature, a phenomenon in which oxygen is released from the oxide semiconductor used for the oxide semiconductor film T110 and the carrier concentration is increased is caused in some cases; therefore, the upper limit of the temperature is a temperature at which the phenomenon is not caused.

### <<Conductive Film T122a, Gate Electrode T122c>>

For a conductive film used for the conductive film T122a and the gate electrode T122c, an oxide containing indium may be used. For example, a light-transmitting conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, or indium tin oxide to which silicon oxide is added can be used. Furthermore, the conductive film that can be used for the conductive film T122a and the gate electrode T122c can be formed by a sputtering method, for example.

Note that the structures, methods, and the like described in this embodiment can be used as appropriate in combination with any of the structures, methods, and the like described in other embodiments.

### Embodiment 6

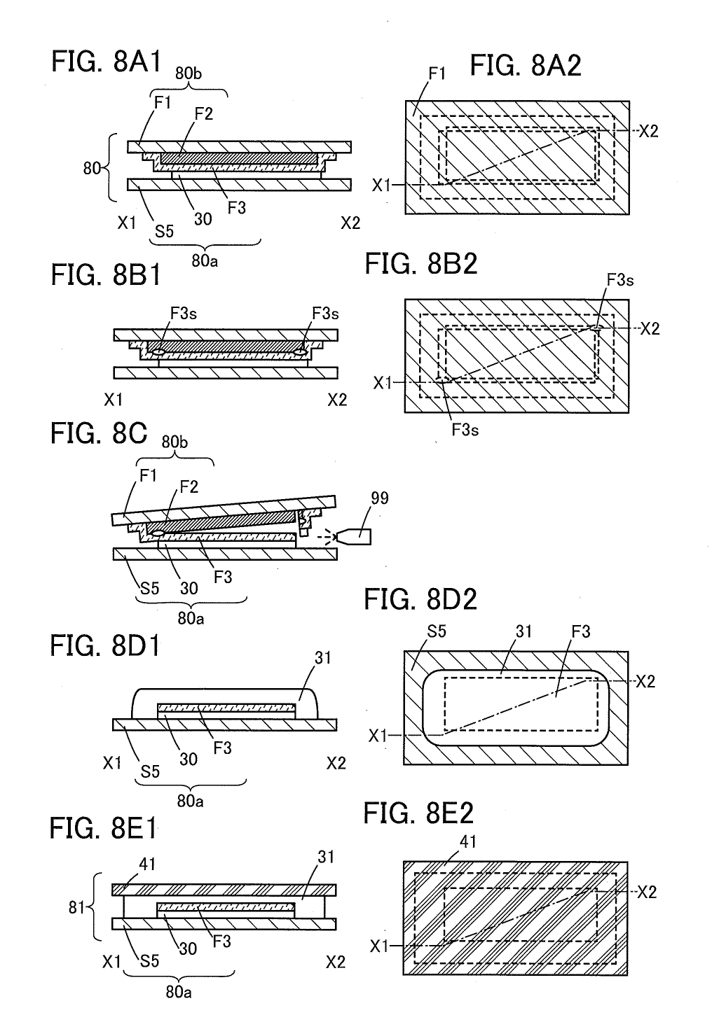

In this embodiment, a method for manufacturing a stack body that can be used in the manufacture of the input/output device of one embodiment of the present invention will be described with reference to FIGS. 8A1, 8A2, 8B1, 8B2, 8C, 8D1, 8D2, 8E1, and 8E2.

FIGS. 8A1 to 8E2 are schematic views illustrating a process of manufacturing the stack body. Cross-sectional views illustrating structures of a process member and the stack body are shown on the left side of FIGS. 8A1 to 8E2, and top views corresponding to the cross-sectional views except FIG. 8C are shown on the right side.

### <Method for Manufacturing Stack Body>

A method for manufacturing a stack body 81 from a process member 80 will be described below with reference to FIGS. 8A1 to 8E2.

The process member 80 includes a first substrate F1, a first separation layer F2 on the first substrate F1, a first layer F3 to be separated (hereinafter simply referred to as the first layer F3) whose one surface is in contact with the first separation layer F2, a bonding layer 30 whose one surface is in contact with the other surface of the first layer F3, and a base S5 in contact with the other surface of the bonding layer 30 (FIGS. 8A1 and 8A2).

Note that the structure of the process member 80 will be described in detail in Embodiment 8.

### <<Formation of Separation Trigger>>

The process member 80 in which separation triggers F3s are formed near end portions of the bonding layer 30 is prepared.

The separation triggers F3s are formed by separating part of the first layer F3 from the first substrate F1.

Part of the first layer F3 can be separated from the first separation layer F2 by inserting a sharp tip into the first layer F3 from the first substrate F1 side, or by a method using a laser or the like (e.g., a laser ablation method). Thus, the separation triggers F3s can be formed.

### <<First Step>>

The process member 80 in which the separation triggers F3s are formed in advance near end portions of the bonding layer 30 is prepared (see FIGS. 8B 1 and 8B2).

### <<Second Step>>

A one surface layer 80b of the process member 80 is separated. By this step, a first remaining portion 80a is obtained from the process member 80.

Specifically, from the separation triggers F3s formed near the end portions of the bonding layer 30, the first substrate F1 and the first separation layer F2 are separated from the first layer F3 (see FIG. 8C). Thus, the first remaining portion 80a including the first layer F3, the bonding layer 30 whose one surface is in contact with the first layer F3, and the base S5 in contact with the other surface of the bonding layer 30 is obtained.

The separation may be performed while the vicinity of the interface between the first separation layer F2 and the first layer F3 is irradiated with ions to remove static electricity. Specifically, the ions may be generated by an ionizer.

When the first layer F3 is separated from the first separation layer F2, a liquid may be injected into the interface between the first separation layer F2 and the first layer F3. Alternatively, a liquid may be ejected and sprayed by a nozzle 99. For example, as the liquid to be injected or sprayed, water, a polar solvent, or the like can be used.

By injecting the liquid, an influence of static electricity and the like generated with the separation can be reduced. Alternatively, the separation may be performed while a liquid that dissolves the separation layer is injected.

In particular, in the case where a film containing tungsten oxide is used as the first separation layer F2, the first layer F3 is preferably separated while a liquid containing water is injected or sprayed because a stress applied to the first layer F3 due to the separation can be reduced.

### <<Third Step>>

A first bonding layer 31 is formed over the first remaining portion 80a, and the first remaining portion 80a and a first support body 41 are bonded to each other with the first bonding layer 31 (see FIGS. 8D1 and 8D2). By this step, the stack body 81 is obtained using the first remaining portion 80a.

Specifically, the stack body 81 including the first support body 41, the first bonding layer 31, the first layer F3, the bonding layer 30 whose one surface is in contact with the first layer F3, and the base S5 in contact with the other surface of the bonding layer 30 is obtained (see FIGS. 8E1 and 8E2).

To form the bonding layer 30, any of a variety of methods can be used. For example, the bonding layer 30 can be formed with a dispenser, by a screen printing method, or the like. The bonding layer 30 is cured by a method selected depending on its material. For example, when a light curable adhesive is used for the bonding layer 30, light including light having a predetermined wavelength is emitted.

Note that this embodiment can be combined with any of the other embodiments in this specification as appropriate.

### Embodiment 7

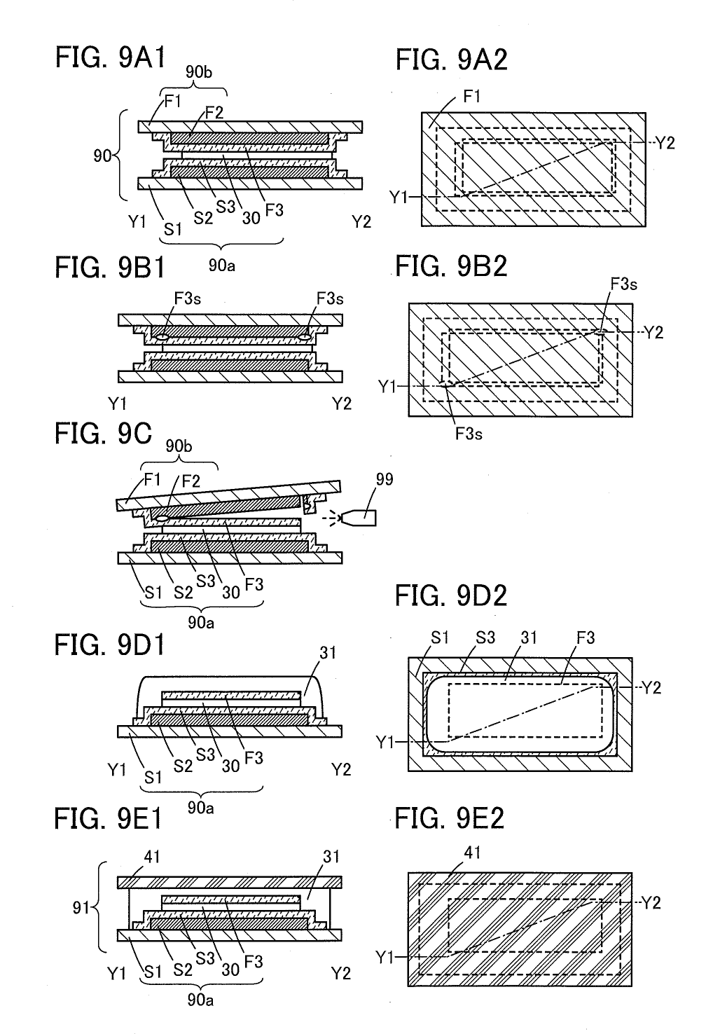

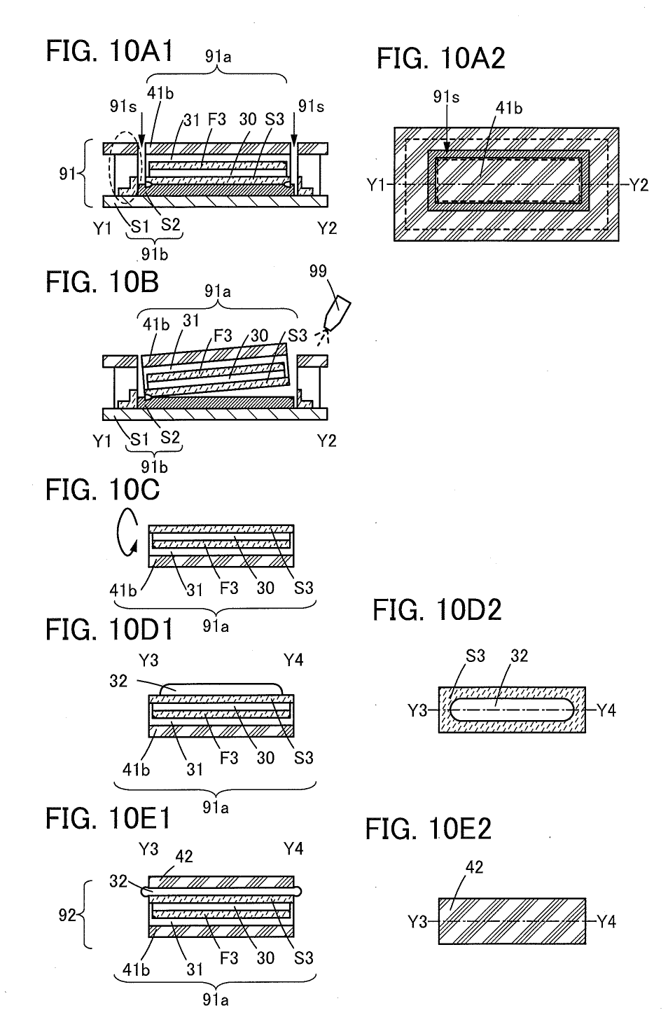

In this embodiment, a method for manufacturing a stack body that can be used in the manufacture of the input/output device of one embodiment of the present invention will be described with reference to FIGS. 9A1, 9A2, 9B1, 9B2, 9C, 9D1, 9D2, 9E1, and 9E2 and FIGS. 10A1, 10A2, 10B, 10C, 10D1, 10D2, 10E1, and 10E2.

FIGS. 9A1 to 9E2 and FIGS. 10A1 to 10E2 are schematic views illustrating a process of manufacturing the stack body. Cross-sectional views illustrating structures of a process member and the stack body are shown on the left side of FIGS. 9A1 to 9E2 and FIGS. 10A1 to 10E2, and top views corresponding to the cross-sectional views except FIGS. 9C, 10B, and 10C are shown on the right side.

### <Method for Manufacturing Stack Body>

A method for manufacturing a stack body 92 from a process member 90 will be described below with reference to FIGS. 9A1 to 9E2 and FIGS. 10A1 to 10E2.

The process member 90 is different from the process member 80 in that the other surface of the bonding layer 30 is in contact with one surface of a second layer S3 to be separated (hereinafter simply referred to as the second layer S3) instead of the base S5.

Specifically, the process member 90 includes a second substrate S1, a second separation layer S2 over the second substrate S1, and the second layer S3 whose other surface is in contact with the second separation layer S2 instead of the base-S5, and differs in that one surface of the second layer S3 is in contact with the other surface of the bonding layer 30.

In the process member 90, the first substrate F1, the first separation layer F2, the first layer F3 whose one surface is in contact with the first separation layer F2, the bonding layer 30 whose one surface is in contact with the other surface of the first layer F3, the second layer S3 whose one surface is in contact with the other surface of the bonding layer 30, the second separation layer S2 whose one surface is in contact with the other surface of the second layer S3, and the second substrate S1 are placed in this order (see FIGS. 9A1 and 9A2).

Note that the structure of the process member 90 will be described in detail in Embodiment 7.

### <<First Step>>

The process member 90 in which the separation triggers F3s are formed near end portions of the bonding layer 30 is prepared (see FIGS. 9B1 and 9B2).

The separation triggers F3s are formed by separating part of the first layer F3 from the first substrate F1.

Part of the first layer F3 can be separated from the first separation layer F2 by inserting a sharp tip into the first layer F3 from the first substrate F1 side, or by a method using a laser or the like (e.g., a laser ablation method). Thus, the separation triggers F3s can be formed.

### <<Second Step>>

A one surface layer 90b of the process member 90 is separated. By this step, a first remaining portion 90a is obtained from the process member 90.

Specifically, from the separation triggers F3s formed near the end portions of the bonding layer 30, the first substrate F1 and the first separation layer F2 are separated from the first layer F3 (see FIG. 9C). Thus, the first remaining portion 90a in which the first layer F3, the bonding layer 30 whose one surface is in contact with the first layer F3, the second layer S3 whose one surface is in contact with the other surface of the bonding layer 30, the second separation layer S2 whose one surface is in contact with the other surface of the second layer S3, and the second substrate S1 are placed in this order is obtained.

The separation may be performed while the vicinity of the interface between the first separation layer F2 and the first layer F3 is irradiated with ions to remove static electricity. Specifically, the ions may be generated by an ionizer.

When the first layer F3 is separated from the first separation layer F2, a liquid may be injected into the interface between the first separation layer F2 and the first layer F3.

Alternatively, a liquid may be ejected and sprayed by the nozzle 99. For example, as the liquid to be injected or sprayed, water, a polar solvent, or the like can be used.

By injecting the liquid, an influence of static electricity and the like generated with the separation can be reduced. Alternatively, the separation may be performed while a liquid that dissolves the separation layer is injected.

In particular, in the case where a film containing tungsten oxide is used as the first separation layer F2, the first layer F3 is preferably separated while a liquid containing water is injected or sprayed because a stress applied to the first layer F3 due to the separation can be reduced.

### <<Third Step>>

The first bonding layer 31 is formed over the first remaining portion 90a (see FIGS. 9D1 and 9D2), and the first remaining portion 90a and the first support body 41 are bonded to each other with the first bonding layer 31. By this step, the stack body 91 is obtained using the first remaining portion 90a.

Specifically, the stack body 91 in which the first support body 41, the first bonding layer 31, the first layer F3, the bonding layer 30 whose one surface is in contact with the first layer F3, the second layer S3 whose one surface is in contact with the other surface of the bonding layer 30, the second separation layer S2 whose one surface is in contact with the other surface of the second layer S3, and the second substrate S1 are placed in this order is obtained (see FIGS. 9E1 and 9E2).

### <<Fourth Step>>

A second separation trigger 91s is formed by separating, from the second substrate S1, part of the second layer S3 near the end portion of the first bonding layer 31 of the stack body 91.

For example, the first support body 41 and the first bonding layer 31 are cut from the first support body 41 side, and part of the second layer S3 is separated from the second substrate S1 along an end portion of the first bonding layer 31 which is newly formed.

Specifically, the first bonding layer 31 and the first support body 41 in a region which is over the second separation layer S2 and in which the second layer S3 is provided are cut with a blade or the like including a sharp tip, and along the newly formed end portion of the first bonding layer 31, the second layer S3 is partly separated from the second substrate S1 (FIGS. 10A1 and 10A2).

By this step, the separation trigger 91s is formed near end portions of a first support body 41b and the first bonding layer 31 which are newly formed.

### <<Fifth Step>>

A second remaining portion 91a is separated from the stack body 91. By this step, the second remaining portion 91a is obtained from the stack body 91 (see FIG. 10C).

Specifically, from the separation trigger 91s formed near the end portion of the first bonding layer 31, the second substrate S1 and the second separation layer S2 are separated from the second layer S3. By this step, the second remaining portion 91a in which the first support body 41b, the first bonding layer 31, the first layer F3, the bonding layer 30 whose one surface is in contact with the first layer F3, and the second layer S3 whose one surface is in contact with the other surface of the bonding layer 30 are placed in this order is obtained.

The separation may be performed while the vicinity of the interface between the second separation layer S2 and the second layer S3 is irradiated with ions to remove static electricity. Specifically, the ions may be generated by an ionizer.

When the second layer S3 is separated from the second separation layer S2, a liquid may be injected into the interface between the second separation layer S2 and the second layer S3. Alternatively, a liquid may be ejected and sprayed by the nozzle 99. For example, as the liquid to be injected or sprayed, water, a polar solvent, or the like can be used.

By injecting the liquid, an influence of static electricity and the like generated with the separation can be reduced. Alternatively, the separation may be performed while a liquid that dissolves the separation layer is injected.

In particular, in the case where a film containing tungsten oxide is used as the second separation layer S2, the second layer S3 is preferably separated while a liquid containing water is injected or sprayed because a stress applied to the second layer S3 due to the separation can be reduced.

### <<Sixth Step>>

A second bonding layer 32 is formed over the second remaining portion 91a (see FIGS. 10D1 and 10D2).

The second remaining portion 91a and a second support body 42 are bonded to each other with the second bonding layer 32. By this step, the stack body 92 is obtained using the second remaining portion 91a (see FIGS. 10E1 and 10E2).

Specifically, the stack body 92 in which the first support body 41b, the first bonding layer 31, the first layer F3, the bonding layer 30 whose one surface is in contact with the first layer F3, the second layer S3 whose one surface is in contact with the other surface of the bonding layer 30, the second bonding layer 32, and the second support body 42 are placed in this order is obtained.

### <Method for Manufacturing Stack Body Having Opening Portion in Support Body>

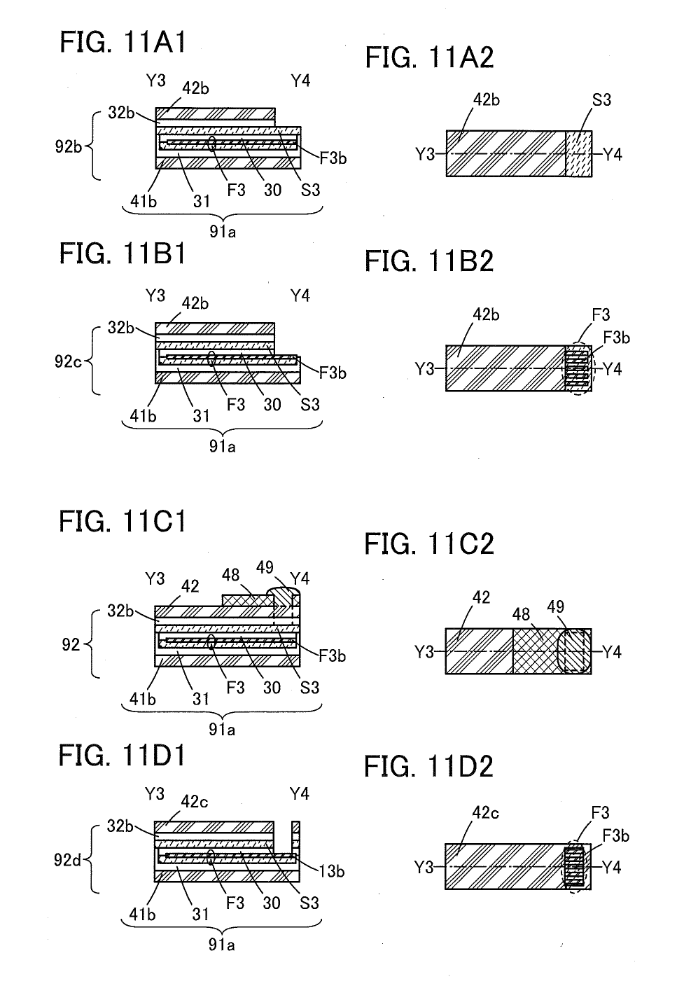

Methods for manufacturing stack bodies each having an opening portion in a support body will be described with reference to FIGS. 11A1, 11A2, 11B1, 11B2, 11C1, 11C2, 11D1, and 11D2.

FIGS. 11A1 to 11D2 illustrate the methods for manufacturing stack bodies each having, in a support body, an opening portion through which part of a separated layer is exposed. Cross-sectional views illustrating structures of the stack bodies are shown on the left side of FIGS. 11A1 to 11D2, and top views corresponding to the cross-sectional views are shown on the right side.

FIGS. 11A1 to 11B2 illustrate a method of manufacturing a stack body 92c having an opening portion by using a second support body 42b which is smaller than the first support body 41b.

FIGS. 11C1 to 11D2 illustrate a method of manufacturing a stack body 92d having an opening portion formed in the second support body 42.

### <<Example 1 of Method for Manufacturing Stack Body Having Opening Portion in Support Body>>

A method for manufacturing a stack body has the same steps as those described above except that the second support body 42b which is smaller than the first support body 41b is used in the sixth step instead of the second support body 42. By this method, a stack body in which part of the second layer S3 is exposed can be manufactured (see FIGS. 11A1 and 11A2).

As the second bonding layer 32, a liquid adhesive can be used. Alternatively, an adhesive whose fluidity is inhibited and which is formed in a single wafer shape in advance (also referred to as a sheet-like adhesive) can be used. By using the sheet-like adhesive, the amount of part of the bonding layer 32 which extends beyond the second support body 42b can be small. In addition, the bonding layer 32 can have a uniform thickness easily.

The exposed part of the second layer S3 may be cut off such that the first layer F3 is exposed (see FIGS. 11B1 and 11B2).

Specifically, with a blade or the like which has a sharp tip, a slit is formed in the exposed part of the second layer S3. Then, for example, an adhesive tape or the like is attached to the exposed part of the second layer S3 to concentrate stress near the slit, and the exposed part of the second layer S3 is separated together with the attached tape or the like, whereby the part of the second layer S3 can be selectively removed.

Moreover, a layer which can suppress the bonding power of the bonding layer 30 to the first layer F3 may be selectively formed on part of the first layer F3. For example, a material which is not easily bonded to the bonding layer 30 may be selectively formed. Specifically, an organic material may be formed into an island shape by evaporation. Thus, part of the bonding layer 30 can be selectively removed together with the second layer S3 easily. As a result, the first layer F3 can be exposed.

Note that for example, in the case where the first layer F3 includes a functional layer and a conductive layer F3b electrically connected to the functional layer, the conductive layer F3b can be exposed in an opening portion in the second stack body 92c. Thus, the conductive layer F3b exposed in the opening portion can be used as a terminal supplied with a signal.

As a result, the conductive layer F3b part of which is exposed in the opening portion can be used as a terminal from which a signal supplied from the functional layer can be extracted, or can be used as a terminal to which a signal to be supplied to the functional layer from an external device can be supplied.

### <<Example 2 of Method for Manufacturing Stack Body Having Opening Portion in Support Body>>

A mask 48 having an opening portion is formed over the stack body 92 such that the opening portion in the mask 48 overlaps with an opening portion formed in the second support body 42. Next, a solvent 49 is dropped into the opening portion in the mask 48. Thus, with the solvent 49, the second support body 42 exposed in the opening portion in the mask 48 can be swelled or dissolved (see FIGS. 11C1 and 11C2).

After the extra solvent 49 is removed, stress is applied by, for example, rubbing the second support body 42 exposed in the opening portion in the mask 48. Thus, the second support body 42 or the like in a portion overlapping with the opening portion in the mask 48 can be removed.

Moreover, with a solvent with which the bonding layer 30 is swelled or dissolved, the first layer F3 can be exposed (see FIGS. 11D1 and 11D2).

Note that this embodiment can be combined with any of the other embodiments in this specification as appropriate.

### Embodiment 8

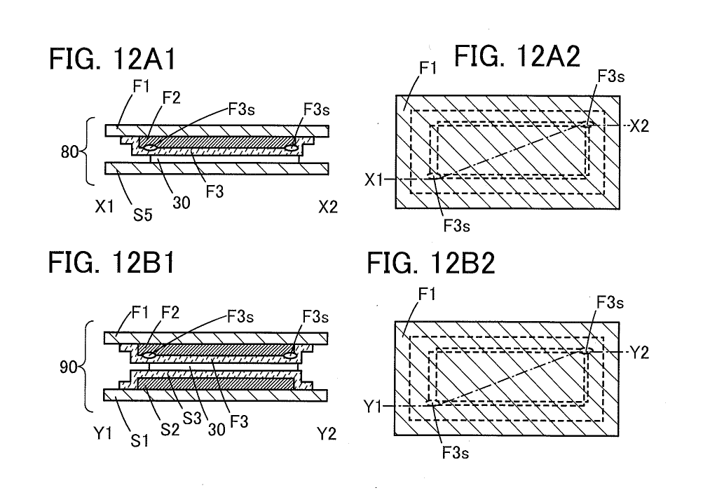

In this embodiment, a structure of a process member that can be processed into the input/output device of one embodiment of the present invention will be described with reference to FIGS. 12A1, 12A2, 12B1, and 12B2.

FIGS. 12A1 to 12B2 are schematic views illustrating structures of process members that can be processed into stack bodies.

FIG. 12A1 is a cross-sectional view illustrating a structure of the process member 80 which can be processed into the stack body, and FIG. 12A2 is a top view corresponding to the cross-sectional view.

FIG. 12B1 is a cross-sectional view illustrating a structure of the process member 90 which can be processed into the stack body, and FIG. 12B2 is a top view corresponding to the cross-sectional view.

### <Structure Example 1 of Process Member>

The process member 80 includes the first substrate F1, the first separation layer F2 on the first substrate F1, the first layer F3 whose one surface is in contact with the first separation layer F2, the bonding layer 30 whose one surface is in contact with the other surface of the first layer F3, and the base S5 in contact with the other surface of the bonding layer 30 (FIGS. 12A1 and 12A2).

Note that the separation triggers F3s may be provided near end portions of the bonding layer 30.

### <<First Substrate>>

There is no particular limitation on the first substrate F1 as long as the first substrate F1 has heat resistance high enough to withstand a manufacturing process and a thickness and a size which can be used in a manufacturing apparatus.

For the first substrate F1, an organic material, an inorganic material, a composite material of an organic material and an inorganic material, or the like can be used.

For example, an inorganic material such as glass, ceramic, or metal can be used for the first substrate F1.

Specifically, alkali-free glass, soda-lime glass, potash glass, crystal glass, or the like can be used for the first substrate F1.

Specifically, a metal oxide film, a metal nitride film, a metal oxynitride film, or the like can be used for the first substrate F1. For example, a silicon oxide film, a silicon nitride film, a silicon oxynitride film, an alumina film, or the like can be used for the first substrate F1.

Specifically, SUS, aluminum, or the like can be used for the first substrate F1.

For example, an organic material such as a resin, a resin film, or plastic can be used for the first substrate F1.

Specifically, a resin film or a resin plate of polyester, polyolefin, polyamide, polyimide, polycarbonate, an acrylic resin, or the like can be used as the first substrate F1.

For example, a composite material such as a resin film to which a metal plate, a thin glass plate, or a film of an inorganic material is attached can be used for the first substrate F1.

For example, a composite material formed by dispersing a fibrous or particulate metal, glass, inorganic material, or the like into a resin film can be used for the first substrate F1.

For example, a composite material formed by dispersing a fibrous or particulate resin, organic material, or the like into an inorganic material can be used for the first substrate F1.

For the first substrate F1, a single-layer material or a stacked-layer material in which a plurality of layers are stacked can be used. For example, a stacked-layer material in which a base, an insulating layer that prevents diffusion of impurities contained in the base, and the like are stacked can be used for the first substrate F1.

Specifically, a stacked-layer material in which glass and one or a plurality of films that prevents diffusion of impurities contained in the glass and that are selected from a silicon oxide film, a silicon nitride film, a silicon oxynitride film, and the like are stacked can be used for the first substrate F1.

Alternatively, a stacked-layer material in which a resin and a film that prevents diffusion of impurities contained in the resin, such as a silicon oxide film, a silicon nitride film, or a silicon oxynitride film are stacked can be used for the first substrate F1.

### <<First Separation Layer>>

The first separation layer F2 is provided between the first substrate F1 and the first layer F3. In the vicinity of the first separation layer F2, a boundary where the first layer F3 can be separated from the first substrate F1 is formed. There is no particular limitation on the first separation layer F2 as long as the first layer F3 can be formed thereon and the first separation layer F2 has heat resistance high enough to withstand the manufacturing process of the first layer F3.

For the first separation layer F2, for example, an inorganic material, an organic resin, or the like can be used.

Specifically, an inorganic material such as a metal containing an element selected from tungsten, molybdenum, titanium, tantalum, niobium, nickel, cobalt, zirconium, zinc, ruthenium, rhodium, palladium, osmium, iridium, and silicon, an alloy containing the element, or a compound containing the element can be used for the first separation layer F2.

Specifically, an organic material such as polyimide, polyester, polyolefin, polyamide, polycarbonate, or an acrylic resin can be used.

For example, a single-layer material or a stacked-layer material in which a plurality of layers are stacked can be used for the first separation layer F2.

Specifically, a material in which a layer containing tungsten and a layer containing an oxide of tungsten are stacked can be used for the first separation layer F2.

The layer containing an oxide of tungsten can be formed by stacking another layer on a layer containing tungsten. Specifically, the layer containing an oxide of tungsten may be formed by a method in which silicon oxide, silicon oxynitride, or the like is stacked on a layer containing tungsten.

The layer containing an oxide of tungsten may be formed by subjecting a surface of a layer containing tungsten to thermal oxidation treatment, oxygen plasma treatment, nitrous oxide (N20) plasma treatment, treatment with a solution with high oxidizing power (e.g., ozone water), or the like.

Specifically, a layer containing polyimide can be used as the first separation layer F2. The layer containing polyimide has heat resistance high enough to withstand various manufacturing steps required to form the first layer F3.

For example, the layer containing polyimide has heat resistance of 200° C. or higher, preferably 250° C. or higher, more preferably 300° C. or higher, still more preferably 350° C. or higher.

By heating a film containing a monomer formed on the first substrate F1, a film containing polyimide obtained by condensation of the monomer can be used.

### <<First Layer>>

There is no particular limitation on the first layer F3 as long as the first layer F3 can be separated from the first substrate F1 and has heat resistance high enough to withstand the manufacturing process.

The boundary where the first layer F3 can be separated from the first substrate F1 may be formed between the first layer F3 and the first separation layer F2 or may be formed between the first separation layer F2 and the first substrate F1.

In the case where the boundary is formed between the first layer F3 and the first separation layer F2, the first separation layer F2 is not included in the stack body. In the case where the boundary is formed between the first separation layer F2 and the first substrate F1, the first separation layer F2 is included in the stack body.

An inorganic material, an organic material, a single-layer material, a stacked-layer material in which a plurality of layers are stacked, or the like can be used for the first layer F3.

For example, an inorganic material such as a metal oxide film, a metal nitride film, or a metal oxynitride film can be used for the first layer F3.

Specifically, a silicon oxide film, a silicon nitride film, a silicon oxynitride film, an alumina film, or the like can be used for the first layer F3.

For example, a resin, a resin film, plastic, or the like can be used for the first layer F3.

Specifically, a polyimide film or the like can be used for the first layer F3.

For example, a material having a structure in which a functional layer overlapping with the first separation layer F2 and an insulating layer that is provided between the first separation layer F2 and the functional layer and can prevent unintended diffusion of impurities which impairs the function of the functional layer are stacked can be used.

Specifically, a 0.7-mm-thick glass plate is used as the first substrate F1, and a stacked-layer material in which a 200-nm-thick silicon oxynitride film and a 30-nm-thick tungsten film are stacked in this order from the first substrate F1 side is used for the first separation layer F2. In addition, a film including a stacked-layer material in which a 600-nm-thick silicon oxynitride film and a 200-nm-thick silicon nitride film are stacked in this order from the first separation layer F2 side can be used as the first layer F3. Note that a silicon oxynitride film refers to a film that includes more oxygen than nitrogen, and a silicon nitride oxide film refers to a film that includes more nitrogen than oxygen.

Specifically, instead of the above first layer F3, a film including a stacked-layer material of a 600-nm-thick silicon oxynitride film, a 200-nm-thick silicon nitride film, a 200-nm-thick silicon oxynitride film, a 140-nm-thick silicon nitride oxide film, and a 100-nm-thick silicon oxynitride film stacked in this order from the first separation layer F2 side can be used as a layer to be separated.

Specifically, a stacked-layer material in which a polyimide film, a layer containing silicon oxide, silicon nitride, or the like and the functional layer are stacked in this order from the first separation layer F2 side can be used.

### <<Functional Layer>>

The functional layer is included in the first layer F3.

For example, a functional circuit, a functional element, an optical element, a functional film, or a layer including a plurality of elements selected from these can be used as the functional layer.

Specifically, a display element that can be used for a display device, a pixel circuit for driving the display element, a driver circuit for driving the pixel circuit, a color filter, a moisture-proof film, and the like, and a layer including two or more selected from these can be given.

### <<Bonding Layer>>

There is no particular limitation on the bonding layer 30 as long as the bonding layer 30 can bond the first layer F3 and the base S5 to each other.

For the bonding layer 30, an inorganic material, an organic material, a composite material of an inorganic material and an organic material, or the like can be used.

For example, a glass layer with a melting point of 400° C. or lower, preferably 300° C. or lower, an adhesive, or the like can be used.

For the bonding layer 30, an organic material such as a photo-curable adhesive, a reactive curable adhesive, a thermosetting adhesive, and/or an anaerobic adhesive can be used.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, an ethylene vinyl acetate (EVA) resin, or the like can be used.

### <<Base>>

There is no particular limitation on the base S5 as long as the base S5 has heat resistance high enough to withstand a manufacturing process and a thickness and a size which can be used in a manufacturing apparatus.

A material similar to that of the first substrate F1, for example, can be used for the base S5.

### <<Separation Trigger>>

In the process member 80, the separation triggers F3s may be formed near the end portions of the bonding layer 30.

The separation triggers F3s are formed by separating part of the first layer F3 from the first substrate F1.

Part of the first layer F3 can be separated from the first separation layer F2 by inserting a sharp tip into the first layer F3 from the first substrate F1 side, or by a method using a laser or the like (e.g., a laser ablation method). Thus, the separation triggers F3s can be formed.

### <Structure Example 2 of Process Member>

A structure of a process member that can be processed into a stack body and is different from the above will be described with reference to FIGS. 12B 1 and 12B2.

The process member 90 is different from the process member 80 in that the other surface of the bonding layer 30 is in contact with one surface of the second layer S3 instead of the base S5.

Specifically, the process member 90 includes the first substrate F1 over which the first separation layer F2 and the first layer F3 whose one surface is in contact with the first separation layer F2 are formed, the second substrate S1 over which the second separation layer S2 and the second layer S3 whose other surface is in contact with the second separation layer S2 are formed, and the bonding layer 30 whose one surface is in contact with the other surface of the first layer F3 and whose other surface is in contact with the one surface of the second layer S3 (see FIGS. 12B 1 and 12B2).

### <<Second Substrate>>

As the second substrate S1, a substrate similar to the first substrate F1 can be used. Note that the second substrate S1 does not necessarily have the same structure as the first substrate F1.

### <<Second Separation Layer>>

As the second separation layer S2, a layer similar to the first separation layer F2 can be used. As the second separation layer S2, a layer different from the first separation layer F2 can be used.

### <<Second Layer>>

As the second layer S3, a layer similar to the first layer F3 can be used. As the second layer S3, a layer different from the first layer F3 can be used.

Specifically, a structure may be employed in which the first layer F3 includes a functional circuit and the second layer S3 includes a functional layer that prevents diffusion of impurities into the functional circuit.

Specifically, a structure may be employed in which the first layer F3 includes a light-emitting element that emits light to the second layer S3, a pixel circuit for driving the light-emitting element, and a driver circuit for driving the pixel circuit, and the second layer S3 includes a color filter that transmits part of light emitted from the light-emitting element and a moisture-proof film that prevents diffusion of impurities into the light-emitting element. Note that the process member with such a structure can be processed into a stack body that can be used as a flexible display device.

Note that this embodiment can be combined with any of the other embodiments in this specification as appropriate.

### Embodiment 9

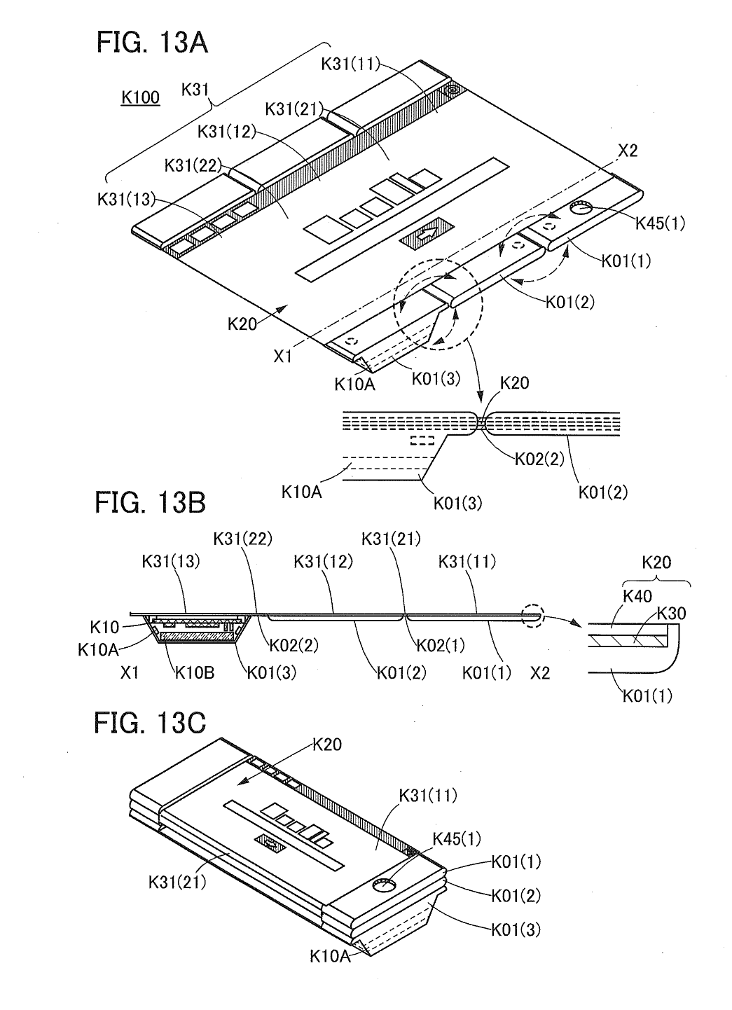

In this embodiment, a structure of a data processing device that can be formed using the input/output device of one embodiment of the present invention will be described with reference to FIGS. 13A to 13C.

FIGS. 13A to 13C illustrate the data processing device in one embodiment of the present invention.

FIG. 13A is a projection view illustrating an input/output device K20 of a data processing device K100 in one embodiment of the present invention which is unfolded. FIG. 13B is a cross-sectional view of the data processing device K100 along the cutting-plane line X1-X2 in FIG. 13A. FIG. 13C is a projection view illustrating the input/output device K20 which is folded.

### <Structure Example of Data Processing Device>

The data processing device K100 described in this embodiment includes the input/output device K20, an arithmetic device K10, and housings K01(1) to K01(3) (see FIGS. 13A to 13C).

### <<Input/Output Device>>

The input/output device K20 includes a display portion K30 and an input device K40. The display portion K30 is supplied with image data V, and the input device K40 supplies sensing data S (see FIG. 13B).

The input/output device K20 includes the input device K40 and the display portion K30 including a region overlapping with the input device K40. Note that the input/output device K20 serves not only as the display portion K30 but also as the input device K40. The input/output device K20 using a touch sensor as the input device K40 and a display panel as the display portion

K30 can be referred to as a touch panel.

Specifically, the input/output device described in any of Embodiments 1 to 4 can be used as the input/output device K20.

### <<Display Portion>>

The display portion K30 includes a region K31 where a first region K31(11), a first bendable region K31(21), a second region K31(12), a second bendable region K31(22), and a third region K31(13) are arranged in stripes in this order (see FIG. 13A).

The display portion K30 can be folded and unfolded along a first fold line formed in the first bendable region K31(21) and a second fold line formed in the second bendable region K31(22) (see FIGS. 13A and 13C).

### <<Arithmetic Device>>

The arithmetic device K10 includes an arithmetic unit and a storage unit that stores a program to be executed by the arithmetic unit. The arithmetic device K10 supplies the image data V and is supplied with the sensing data S.

### <<Housing>>

A housing includes the housing K01(1), a hinge K02(1), the housing K01(2), a hinge K02(2), and the housing K01(3) which are placed in this order.

In the housing K01(3), the arithmetic device K10 is stored. The housings K01(1) to K01(3) hold the input/output device K20, and enable the input/output device K20 to be folded and unfolded (see FIG. 13B).

In this embodiment, the data processing device including the three housings and the two hinges connecting the three housings is given as an example. The input/output device K20 can be folded by being bent at two positions where the hinges are placed.

Note that n (n is a natural number greater than or equal to 2) housings can be connected using (n−1) hinges. Thus, the input/output device K20 can be folded by being bent at (n−1) positions.

The housing K01(1) includes a region overlapping with the first region K31(11) and a button K45(1).

The housing K01(2) includes a region overlapping with the second region K31(12).

The housing K01(3) includes a region overlapping with the third region K31(13) and a region in which the arithmetic device K10, an antenna K10A, and a battery K10B are stored.

The hinge K02(1) includes a region overlapping with the first bendable region K31(21) and connects the housing K01(1) rotatably to the housing K01(2).

The hinge K02(2) includes a region overlapping with the second bendable region K31(22) and connects the housing K01(2) rotatably to the housing K01(3).

The antenna K10A is electrically connected to the arithmetic device K10 and supplies a signal or is supplied with a signal.

In addition, the antenna K10A is wirelessly supplied with power from an externally placed device and supplies power to the battery K10B.

The battery K10B supplies power and the arithmetic device K10 is supplied with power.

Note that a folding sensor having a function of determining whether the housing is folded or unfolded and supplying data showing the state of the housing can be used. For example, the folding sensor can be placed in the housing K01(3), so that the data showing the state of the housing K01 can be supplied to the arithmetic device K10.

For example, the arithmetic device K10 supplied with the data showing the folded state of the housing K01 supplies the image data V to be displayed on the first region K31(11) (see FIG. 13C).

The arithmetic device K10 supplied with the data showing the unfolded state of the housing K01 supplies the image data V to be displayed on the region K31 of the display portion K30 (see FIG. 13A).

Note that this embodiment can be combined with any of the other embodiments in this specification as appropriate.

For example, in this specification and the like, an explicit description “X and Y are connected” means that X and Y are electrically connected, X and Y are functionally connected, and

X and Y are directly connected. Accordingly, without being limited to a predetermined connection relation, for example, a connection relation shown in drawings or text, another connection relation is included in the drawings or the text.

Here, X and Y each denote an object (e.g., a device, an element, a circuit, a wiring, an electrode, a terminal, a conductive film, or a layer).

For example, in the case where X and Y are directly connected, X and Y are connected without an element that enables electrical connection between X and Y (e.g., a switch, a transistor, a capacitor, an inductor, a resistor, a diode, a display element, a light-emitting element, or a load) interposed between X and Y.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is conducting or not conducting (is turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, and a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and X and Y are electrically connected.

Note that in this specification and the like, an explicit description “X and Y are electrically connected” means that X and Y are electrically connected (i.e., the case where X and Y are connected with another element or circuit provided therebetween), X and Y are functionally connected (i.e., the case where X and Y are functionally connected with another circuit provided therebetween), and X and Y are directly connected (i.e., the case where X and Y are connected without another element or circuit provided therebetween). That is, in this specification and the like, the explicit expression “X and Y are electrically connected” is the same as the explicit simple expression “X and Y are connected”.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit structure is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path”. It is also possible to use the expression “a source (or a first terminal or the like) of a transistor is electrically connected to X through at least Z1 on a first connection path, the first connection path does not include a second connection path, the second connection path includes a connection path through the transistor, a drain (or a second terminal or the like) of the transistor is electrically connected to Y through at least Z2 on a third connection path, and the third connection path does not include the second connection path”. Still another example of the expression is “source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit structure is defined by an expression similar to the above examples, a source (or a first terminal or the like) and a drain (or a second terminal or the like) of a transistor can be distinguished from each other to specify the technical scope.

Note that one embodiment of the present invention is not limited to these expressions which are just examples. Here, each of X, Y, Z1, and Z2 denotes an object (e.g., a device, an element, a circuit, a wiring, an electrode, a terminal, a conductive film, a layer, or the like).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

### EXPLANATION OF REFERENCE

30: bonding layer, 31: bonding layer, 32: bonding layer, 41: support body, 41b: support body, 42: support body, 42b: support body, 48: mask, 49: solvent, 80: process member, 80a: remaining portion, 80b: surface layer, 81: stack body, 90: process member, 90a: remaining portion, 90b: surface layer, 91: stack body, 91a: remaining portion, 91s: trigger, 92: stack body, 92c: stack body, 92d: stack body, 99: nozzle, 100: input/output device, 100B: input/output device, 103: input/output circuit, 103B: input/output circuit, 104: conversion circuit, 200: input/output device, 200B: input/output device, 200C: input/output device, 200D: input/output device, 201: region, 202: pixel, 202B: pixel, 202R: sub-pixel, 203: input/output circuit, 203B: input/output circuit, 204: conversion circuit, 209: flexible printed board, 210: base, 210a: barrier film, 210b: base, 210c: resin layer, 211: wiring, 219: terminal, 221: insulating layer, 228: partition, 250R: light-emitting element, 260: sealant, 267BM: light-blocking layer, 267p: protective film, 267R: coloring layer, 270: base, 270a: barrier film, 270b: base, 270c: resin layer, 280B: display module, 280G: display module, 280R: display module, 280Y: display module, F1: substrate, F2: separation layer, F3: layer to be separated, F3b: conductive layer, F3s: trigger, G1: first control line, G2: second control line, G3: third control line, G4: fourth control line, OUT: terminal, BR: wiring, VPO: wiring, K01: housing, K02: hinge, K10: arithmetic device, K10A: antenna, K10B: battery, K20: input/output device, K30: display portion, K31: region, K45: button, K100: data processing device, L1: wiring, L2: wiring, L3: wiring, L4: wiring, M0: driving transistor, M1: transistor, M2: transistor, M3: transistor, M4: transistor, M5: transistor, M6: transistor, MD: transistor, S1: substrate, S2: separation layer, S3: layer to be separated, S5: base, T1: period, T2: period, T3: period, T4: period, T11: period, T12: period, T21: period, T22: period, T31: period, T41: period, T102: substrate, T104a: gate electrode, T106: insulating film, T107: insulating film, T108: insulating film, T110: oxide semiconductor film, T112: conductive film, T112a: electrode, T112b: electrode, T114: insulating film, T116: insulating film, T118: insulating film, T120: insulating film; T122a: conductive film, T122c: gate electrode, T142a: opening, T142e: opening, and T151: transistor.

This application is based on Japanese Patent Application serial no. 2014-088971 filed with Japan Patent Office on Apr. 23, 2014, the entire contents of which are hereby incorporated by reference.

1. An input/output device comprising:
an input/output circuit supplied with a selection signal, a control signal, a display signal including display data, and a sensing signal and capable of supplying a potential based on the sensing signal or a current based on the display signal;
a conversion circuit supplied with a high power supply potential and capable of supplying a potential based on the high power supply potential and supplying sensing data based on the sensing signal;
a sensing element capable of supplying the sensing signal; and
a display element supplied with the current,
wherein the input/output circuit comprises:
a first transistor comprising a gate electrically connected to a first control line capable of supplying the selection signal and a first electrode electrically connected to a signal line capable of supplying the display signal;
a second transistor comprising a gate electrically connected to a second control line capable of supplying the control signal and a first electrode electrically connected to a first wiring; and
a driving transistor comprising a gate electrically connected to a second electrode of the first transistor, a first electrode electrically connected to a second wiring, and a second electrode electrically connected to a second electrode of the second transistor,
wherein the conversion circuit comprises:
a transistor comprising a gate electrically connected to one of wirings, a first electrode electrically connected to the other one of wirings, and a second electrode electrically connected to the second wiring, wherein each of the wirings is capable of supplying the high power supply potential; and
a terminal electrically connected to the second wiring and capable of supplying the sensing data,
wherein the sensing element comprises a first electrode electrically connected to the second electrode of the first transistor and a second electrode electrically connected to the second electrode of the second transistor, and
wherein the display element comprises a first electrode electrically connected to the second electrode of the driving transistor and a second electrode electrically connected to a third wiring.

2. The input/output device according to claim 1, wherein the sensing signal supplied by the sensing element includes a current which changes with a change in capacitance.

3. The input/output device according to claim 1, wherein the display element comprises the first electrode, the second electrode overlapping with the first electrode, and a layer containing a light-emitting organic compound between the first electrode and the second electrode.

4. An input/output device comprising:
an input/output circuit supplied with a selection signal, a first control signal, a second control signal, a third control signal, a display signal including display data, and a sensing signal and capable of supplying a potential based on the sensing signal or a current based on the display signal;
a conversion circuit supplied with a high power supply potential and capable of supplying a potential based on the high power supply potential and supplying sensing data based on the sensing signal;
a sensing element capable of supplying the sensing signal; and
a display element supplied with the current,
wherein the input/output circuit comprises:
a first transistor comprising a gate electrically connected to a first control line capable of supplying the selection signal and a first electrode electrically connected to a signal line capable of supplying the display signal;
a second transistor comprising a gate electrically connected to a second control line capable of supplying the first control signal and a first electrode electrically connected to a first wiring;
a third transistor comprising a gate electrically connected to a third control line capable of supplying the second control signal and a first electrode electrically connected to a second electrode of the second transistor;
a fourth transistor comprising a gate electrically connected to a fourth control line capable of supplying the third control signal and a first electrode electrically connected to a second electrode of the first transistor;
a fifth transistor comprising a gate electrically connected to the first control line capable of supplying the selection signal, a first electrode electrically connected to a second electrode of the fourth transistor, and a second electrode electrically connected to a fourth wiring; and
a driving transistor comprising a gate electrically connected to the second electrode of the fourth transistor, a first electrode electrically connected to a second wiring, and a second electrode electrically connected to the second electrode of the second transistor,
wherein the conversion circuit comprises:
a transistor comprising a gate electrically connected to one of wirings, a first electrode electrically connected to the other one of wirings, and a second electrode electrically connected to the second wiring, wherein each of the wirings is capable of supplying the high power supply potential; and
a terminal electrically connected to the second wiring and capable of supplying the sensing data,
wherein the sensing element comprises a first electrode electrically connected to the second electrode of the first transistor and a second electrode electrically connected to the second electrode of the second transistor, and
wherein the display element comprises a first electrode electrically connected to a second electrode of the third transistor and a second electrode electrically connected to a third wiring.

5. The input/output device according to claim 4, wherein the sensing signal supplied by the sensing element includes a current which changes with a change in capacitance.

6. The input/output device according to claim 4, wherein the display element comprises the first electrode, the second electrode overlapping with the first electrode, and a layer containing a light-emitting organic compound between the first electrode and the second electrode.

7. A method for driving an input/output device, the input/output device comprising:
an input/output circuit supplied with a selection signal, a control signal, a display signal including display data, and a sensing signal and capable of supplying a potential based on the sensing signal or a current based on the display signal;
a conversion circuit supplied with a high power supply potential and capable of supplying a potential based on the high power supply potential and supplying sensing data based on the sensing signal;
a sensing element capable of supplying the sensing signal; and
a display element supplied with the current,
wherein the input/output circuit comprises:
a first transistor comprising a gate electrically connected to a first control line capable of supplying the selection signal and a first electrode electrically connected to a signal line capable of supplying the display signal;
a second transistor comprising a gate electrically connected to a second control line capable of supplying the control signal and a first electrode electrically connected to a first wiring; and
a driving transistor comprising a gate electrically connected to a second electrode of the first transistor, a first electrode electrically connected to a second wiring, and a second electrode electrically connected to a second electrode of the second transistor,
wherein the conversion circuit comprises:
a transistor comprising a gate electrically connected to one of wirings, a first electrode electrically connected to the other one of wirings, and a second electrode electrically connected to the second wiring, wherein each of the wirings is capable of supplying the high power supply potential; and
a terminal electrically connected to the second wiring and capable of supplying the sensing data,
wherein the sensing element comprises a first electrode electrically connected to the second electrode of the first transistor and a second electrode electrically connected to the second electrode of the second transistor, and
wherein the display element comprises a first electrode electrically connected to the second electrode of the driving transistor and a second electrode electrically connected to a third wiring,
the method comprising:
a first step of supplying the selection signal capable of turning on the first transistor, the control signal capable of turning on the second transistor, and the display signal having a reference potential;
a second step of supplying the selection signal capable of turning off the first transistor and the control signal capable of turning on the second transistor, supplying the potential based on the high power supply potential so that the driving transistor supplies the current based on the sensing signal supplied by the sensing element, and making the conversion circuit supply the sensing data based on the sensing signal;
a third step of supplying the selection signal capable of turning on the first transistor, the control signal capable of turning off the second transistor, and the display signal having a potential based on the display data; and
a fourth step of supplying the selection signal capable of turning off the first transistor and the control signal capable of turning off the second transistor and supplying the potential based on the high power supply potential so that the driving transistor supplies the current based on the display signal supplied in the third step.

8. The method for driving the input/output device according to claim 7, wherein the sensing signal supplied by the sensing element includes a current which changes with a change in capacitance.

9. The method for driving the input/output device according to claim 7, wherein the display element comprises the first electrode, the second electrode overlapping with the first electrode, and a layer containing a light-emitting organic compound between the first electrode and the second electrode.

10. A method for driving an input/output device, the input/output device comprising:
an input/output circuit supplied with a selection signal, a first control signal, a second control signal, a third control signal, a display signal including display data, and a sensing signal and capable of supplying a potential based on the sensing signal or a current based on the display signal;
a conversion circuit supplied with a high power supply potential and capable of supplying a potential based on the high power supply potential and supplying sensing data based on the sensing signal;
a sensing element capable of supplying the sensing signal; and
a display element supplied with the current,
wherein the input/output circuit comprises:
a first transistor comprising a gate electrically connected to a first control line capable of supplying the selection signal and a first electrode electrically connected to a signal line capable of supplying the display signal;
a second transistor comprising a gate electrically connected to a second control line capable of supplying the first control signal and a first electrode electrically connected to a first wiring;
a third transistor comprising a gate electrically connected to a third control line capable of supplying the second control signal and a first electrode electrically connected to a second electrode of the second transistor;
a fourth transistor comprising a gate electrically connected to a fourth control line capable of supplying the third control signal and a first electrode electrically connected to a second electrode of the first transistor;
a fifth transistor comprising a gate electrically connected to the first control line capable of supplying the selection signal, a first electrode electrically connected to a second electrode of the fourth transistor, and a second electrode electrically connected to a fourth wiring; and
a driving transistor comprising a gate electrically connected to the second electrode of the fourth transistor, a first electrode electrically connected to a second wiring, and a second electrode electrically connected to the second electrode of the second transistor,
wherein the conversion circuit comprises:
a transistor comprising a gate electrically connected to one of wirings, a first electrode electrically connected to the other one of wirings, and a second electrode electrically connected to the second wiring, wherein each of the wirings is capable of supplying the high power supply potential; and
a terminal electrically connected to the second wiring and capable of supplying the sensing data,
wherein the sensing element comprises a first electrode electrically connected to the second electrode of the first transistor and a second electrode electrically connected to the second electrode of the second transistor, and
wherein the display element comprises a first electrode electrically connected to a second electrode of the third transistor and a second electrode electrically connected to a third wiring,
the method comprising:
a first step of supplying the selection signal capable of turning off the first transistor and the fifth transistor, the first control signal capable of turning off the second transistor, the second control signal capable of turning on the third transistor, and the third control signal capable of turning off the fourth transistor;
a second step of supplying the selection signal capable of turning on the first transistor and the fifth transistor, the first control signal capable of turning off the second transistor, the second control signal capable of turning off the third transistor, the third control signal capable of turning off the fourth transistor, and the display signal having a reference potential;
a third step of supplying the selection signal capable of turning off the first transistor and the fifth transistor, the first control signal capable of turning on the second transistor, the second control signal capable of turning off the third transistor, and the third control signal capable of turning on the fourth transistor, supplying the potential based on the high power supply potential to the second wiring so that the driving transistor supplies the current based on the sensing signal supplied by the sensing element, and making the conversion circuit supply the sensing data based on the sensing signal;
a fourth step of supplying the selection signal capable of turning off the first transistor and the fifth transistor, the first control signal capable of turning off the second transistor, the second control signal capable of turning on the third transistor, and the third control signal capable of turning off the fourth transistor;
a fifth step of supplying the selection signal capable of turning on the first transistor and the fifth transistor, the first control signal capable of turning off the second transistor, the second control signal capable of turning off the third transistor, the third control signal capable of turning off the fourth transistor, and the display signal based on the display data; and
a sixth step of supplying the selection signal capable of turning off the first transistor and the fifth transistor, the first control signal capable of turning off the second transistor, the second control signal capable of turning on the third transistor, and the third control signal capable of turning on the fourth transistor, and supplying the high power supply potential to the second wiring so that the driving transistor supplies the current based on the display signal supplied in the fifth step.

11. The method for driving the input/output device according to claim 10, wherein the sensing signal supplied by the sensing element includes a current which changes with a change in capacitance.

12. The method for driving the input/output device according to claim 10, wherein the display element comprises the first electrode, the second electrode overlapping with the first electrode, and a layer containing a light-emitting organic compound between the first electrode and the second electrode.

13. An input/output device comprising:
a plurality of pixels arranged in a matrix;
a plurality of first control lines capable of supplying a selection signal;
a plurality of second control lines capable of supplying a control signal;
a plurality of signal lines capable of supplying a display signal including display data;
a plurality of first wirings capable of supplying a first power supply potential;
a plurality of second wirings capable of supplying a potential based on a high power supply potential;
a plurality of third wirings capable of supplying a second power supply potential;
a conversion circuit electrically connected to one of the plurality of second wirings, the conversion circuit supplied with the high power supply potential, wherein the conversion circuit is capable of supplying the potential based on the high power supply potential and supplying sensing data based on a sensing signal; and
a base supporting the plurality of pixels, the plurality of first control lines, the plurality of second control lines, the plurality of signal lines, the plurality of first wirings, the plurality of second wirings, and the plurality of third wirings,
wherein one of the plurality of pixels is electrically connected to one of the plurality of first control lines, one of the plurality of second control lines, one of the plurality of signal lines, one of the plurality of first wirings, the one of the plurality of second wirings, and one of the plurality of third wirings,
wherein the one of the plurality of pixels comprises:
an input/output circuit supplied with the selection signal, the control signal, the display signal, and the sensing signal and capable of supplying a potential based on the sensing signal;
a sensing element capable of supplying the sensing signal; and
a display element supplied with the current,
wherein the input/output circuit comprises:
a first transistor comprising a gate electrically connected to the one of the plurality of first control lines capable of supplying the selection signal and a first electrode electrically connected to the one of the plurality of signal lines capable of supplying the display signal;
a second transistor comprising a gate electrically connected to the one of the plurality of second control lines capable of supplying the control signal and a first electrode electrically connected to the one of the plurality of first wirings; and
a driving transistor comprising a gate electrically connected to a second electrode of the first transistor, a first electrode electrically connected to the one of the plurality of second wirings, and a second electrode electrically connected to a second electrode of the second transistor,
wherein the conversion circuit comprises:
a transistor comprising a gate electrically connected to one of wirings, a first electrode electrically connected to the other one of wirings, and a second electrode electrically connected to the one of the plurality of second wirings, wherein each of the wirings is capable of supplying the high power supply potential; and
a terminal electrically connected to the one of the plurality of second wirings and capable of supplying the sensing data,
wherein the sensing element comprises a first electrode electrically connected to the second electrode of the first transistor and a second electrode electrically connected to the second electrode of the second transistor, and
wherein the display element comprises a first electrode electrically connected to the second electrode of the driving transistor and a second electrode electrically connected to the one of the plurality of third wirings.

14. The input/output device according to claim 13, wherein the sensing signal supplied by the sensing element includes a current which changes with a change in capacitance.

15. The input/output device according to claim 13, wherein the display element comprises the first electrode, the second electrode overlapping with the first electrode, and a layer containing a light-emitting organic compound between the first electrode and the second electrode.

16. The input/output device according to claim 13, wherein the conversion circuit is supported by the base.

17. An input/output device comprising:
a plurality of pixels arranged in a matrix;
a plurality of first control lines capable of supplying a selection signal;
a plurality of second control lines capable of supplying a first control signal;
a plurality of third control lines capable of supplying a second control signal;
a plurality of fourth control lines capable of supplying a third control signal;
a plurality of signal lines capable of supplying a display signal including display data;
a plurality of first wirings capable of supplying a first power supply potential;
a plurality of second wirings capable of supplying a potential based on a high power supply potential;
a plurality of third wirings capable of supplying a second power supply potential;
a plurality of fourth wirings capable of supplying a third power supply potential;
a conversion circuit electrically connected to one of the plurality of second wirings, the conversion circuit supplied with the high power supply potential, wherein the conversion circuit is capable of supplying the potential based on the high power supply potential and supplying sensing data based on a sensing signal; and
a base supporting the plurality of pixels, the plurality of first control lines, the plurality of second control lines, the plurality of third control lines, the plurality of fourth control lines, the plurality of signal lines, the plurality of first wirings, the plurality of second wirings, the plurality of third wirings, and the plurality of fourth wirings,
wherein one of the plurality of pixels is electrically connected to one of the plurality of first control lines, one of the plurality of second control lines, one of the plurality of third control lines, one of the plurality of fourth control lines, one of the plurality of signal lines, one of the plurality of first wirings, the one of the plurality of second wirings, one of the plurality of third wirings, and one of the plurality of fourth wirings,
wherein the one of the plurality of pixels comprises:
an input/output circuit supplied with the selection signal, the first to third control signals, the display signal, and the sensing signal and capable of supplying a potential based on the sensing signal;
a sensing element capable of supplying the sensing signal; and
a display element supplied with a predetermined current,
wherein the input/output circuit comprises:
a first transistor comprising a gate electrically connected to the one of the plurality of first control lines capable of supplying the selection signal and a first electrode electrically connected to the one of the plurality of signal lines capable of supplying the display signal;
a second transistor comprising a gate electrically connected to the one of the plurality of second control lines capable of supplying the first control signal and a first electrode electrically connected to the one of the plurality of first wirings;
a third transistor comprising a gate electrically connected to the one of the plurality of third control lines capable of supplying the second control signal and a first electrode electrically connected to a second electrode of the second transistor;
a fourth transistor comprising a gate electrically connected to the one of the plurality of fourth control lines capable of supplying the third control signal and a first electrode electrically connected to a second electrode of the first transistor;
a fifth transistor comprising a gate electrically connected to the one of the plurality of first control lines capable of supplying the selection signal, a first electrode electrically connected to a second electrode of the fourth transistor, and a second electrode electrically connected to the one of the plurality of fourth wirings; and
a driving transistor comprising a gate electrically connected to the second electrode of the fourth transistor, a first electrode electrically connected to the one of the plurality of second wirings, and a second electrode electrically connected to the second electrode of the second transistor,
wherein the conversion circuit comprises:
a transistor comprising a gate electrically connected to one of wirings, a first electrode electrically connected to the other one of wirings, and a second electrode electrically connected to the one of the plurality of second wirings, wherein each of the wirings is capable of supplying the high power supply potential; and
a terminal electrically connected to the one of the plurality of second wirings and capable of supplying the sensing data,
wherein the sensing element comprises a first electrode electrically connected to the second electrode of the first transistor and a second electrode electrically connected to the second electrode of the second transistor, and
wherein the display element comprises a first electrode electrically connected to a second electrode of the third transistor and a second electrode electrically connected to the one of the plurality of third wirings.

18. The input/output device according to claim 17, wherein the sensing signal supplied by the sensing element includes a current which changes with a change in capacitance.

19. The input/output device according to claim 17, wherein the display element comprises the first electrode, the second electrode overlapping with the first electrode, and a layer containing a light-emitting organic compound between the first electrode and the second electrode.

20. The input/output device according to claim 17, wherein the conversion circuit is supported by the base.
